(19) United States
(12) Patent Application Publication
(10) Pub. No.: US 2025/0105225 A1
(43) Pub. Date: Mar. 27, 2025

(54) ACCELERATOR STRUCTURE, METHOD FOR GENERATING ACCELERATOR STRUCTURE, AND DEVICE THEREOF

(71) Applicant: Cambricon (Xi'an) Semiconductor Co., Ltd., Xi'an (CN)

(72) Inventors: Zhiwei QIU, Xi'an (CN); Shuai CHEN, Xi'an (CN); Song GAO, Xi'an (CN); Yunliang ZHUANG, Xi'an (CN)

(21) Appl. No.: 18/706,216

(22) PCT Filed: Sep. 29, 2022
(86) PCT No.: PCT/CN2022/122375

§ 371 Date: Dec. 7, 2024

(30) Foreign Application Priority Data
May 11, 2021 (CN) 202111308266.9

(51) Int. Cl. H01L 25/16; H01L 21/66; H01L 23/36; H01L 23/538

(52) U.S. Cl. CPC H01L 25/16; H01L 22/12; H01L 23/36; H01L 23/5384; H01L 23/5386

(57) ABSTRACT

The present disclosure relates to an accelerator structure and a device thereof, a method for generating an accelerator structure, and a computer-readable storage medium, a computer program product and a computer apparatus thereof. The accelerator structure of the present disclosure includes: a computing layer, which is provided with a plurality of chip on wafer (CoW) units, each of which includes a first die group and a second die group; a module layer, which is provided with a power module die group and an interface module die group; and a line layer, which is arranged between the computing layer and the module layer. The power module die group supplies power to the first die group and the second die group through the line layer. The first die group and the second die group output a computing result through the interface module die group via the line layer.

### CROSS REFERENCE OF RELATED APPLICATION

The present disclosure is a 371 of international application PCT/CN2022/122375, filed Sep. 29, 2022, which claims priority of Chinese Patent Application No. 202111308266.9 with the title of “Accelerator Structure, Method for Generating Accelerator Structure, and Device Therefor” and filed on Nov. 5, 2021.

### TECHNICAL FIELD

The present disclosure generally relates to the field of semiconductors. More specifically, the present disclosure relates to an accelerator structure and a device thereof, a method for generating an accelerator structure, and a computer-readable storage medium, a computer program product and a computer apparatus thereof.

### BACKGROUND

With the rapid development in the artificial intelligence (AI) field, the application demand for high-performance computing is becoming more and more intense. From recommendation engines used in e-commerce to self-driving cars, people are already inseparable from AI solutions in their lives, and the rapid spread of the AI solutions in the market has driven exponential growth in computing demand. According to the statistics, since 2012, the computing requirements of deep learning networks are doubling roughly every 3.5 months.

In order to meet the computing performance and storage bandwidth requirements of high-performance computing applications, microwafer-based multi-chip integration solutions have emerged in various accelerators from a central processing unit (CPU)/a graphics processing unit (GPU) to an application specific integrated circuit (ASIC). In addition to yield and cost-effectiveness, these new chips also require short and dense interconnections to enable chip-to-chip (C2C) input and output (IO) circuits and maintain low power consumption through advanced packaging technology.

Taiwan Semiconductor Manufacturing Company has developed an extremely large and compact system solution called an integrated fan-out system on wafer (InFO_SoW) technology that integrates a known chip array with power and heat dissipation modules for high-performance computing. InFO_SoW reduces the use of substrates and printed circuit boards by acting as the carrier itself. A multi-chip array that is tightly packaged within the compact system enables the solution to reap wafer-scale benefits, such as chip-to-chip communication with low latency, high bandwidth density, and low power distribution network (PDN) impedance, thus obtaining higher computing performance and power efficiency.

However, the existing InFO_SoW technology only integrates a plurality of single chips into the system, and such integration efficiency is still not enough to meet the requirements of various accelerators for large-scale chip integration. Therefore, a denser chip integration solution based on the InFO_SoW technology is urgently needed.

### SUMMARY

To at least partially address the technical issues mentioned in the background, the present disclosure provides an accelerator structure and a device thereof, a method for generating an accelerator structure, and a computer-readable storage medium, a computer program product and a computer apparatus thereof.

A first aspect of the present disclosure discloses an accelerator structure, including a computing layer, a module layer, and a line layer. The computing layer is provided with a plurality of chip on wafer (CoW) units, each of which includes a first die group and a second die group. The module layer is provided with a power module die group and an interface module die group. The line layer is arranged between the computing layer and the module layer. The power module die group supplies power to the first die group and the second die group through the line layer. The first die group and the second die group output a computing result through the interface module die group via the line layer.

A second aspect of the present disclosure discloses an integrated circuit apparatus, including the above-mentioned accelerator structure. Moreover, the present disclosure also discloses a board card, including the above-mentioned integrated circuit apparatus.

A third aspect of the present disclosure discloses a method for generating an accelerator structure, including: generating a line layer; generating a computing layer on one side of the line layer, where the computing layer is provided with a plurality of chip on wafer (CoW) units, each of which includes a first die group and a second die group; and generating a module layer on the other side of the line layer, where the module layer is provided with a power module die group and an interface module die group. The power module die group supplies power to the first die group and the second die group through the line layer. The first die group and the second die group output a computing result through the interface module die group via the line layer.

A fourth aspect of the present disclosure discloses a computer-readable storage medium, on which a computer program code for generating an accelerator structure is stored. When the computer program code is run by a processing apparatus, the above-mentioned method is performed.

A fifth aspect of the present disclosure discloses a computer program product, including a computer program for generating an accelerator structure, where steps of the above-mentioned method are implemented when the computer program is executed by a processor.

A sixth aspect of the present disclosure discloses a computer apparatus, including a memory, a processor, and a computer program stored in the memory, where the processor executes the computer program to implement steps of the above-mentioned method.

By integrating CoW units into InFO_SoW, the present disclosure may significantly improve integration efficiency, so as to meet the requirements of various accelerators for large-scale chip integration and achieve the technical efficacy of integrating ultra-large computing power.

### BRIEF DESCRIPTION OF DRAWINGS

By reading the following detailed description with reference to drawings, the above and other objects, features and technical effects of exemplary implementations of the present disclosure will become easier to understand. In the drawings, several implementations of the present disclosure are shown in an exemplary manner rather than a restrictive manner, and the same or corresponding reference numerals indicate the same or corresponding parts. In the drawings,

FIG. 1 is a cutaway view of InFO_SoW;

FIG. 2 is a top view of exemplary InFO_SoW;

FIG. 3 is a layout diagram of a CoW unit according to an embodiment of the present disclosure;

FIG. 4 is another layout diagram of the CoW unit according to an embodiment of the present disclosure;

FIG. 5 is another layout diagram of the CoW unit according to an embodiment of the present disclosure;

FIG. 6 is a schematic structural diagram of an exemplary board card;

FIG. 7 is a structural diagram of an integrated circuit apparatus according to an embodiment of the present disclosure;

FIG. 8 is a cutaway view of an accelerator structure where CoW units are combined with InFO_SoW according to an embodiment of the present disclosure;

FIG. 9 is a cutaway view of an accelerator structure where CoW units are combined with InFO_SoW according to another embodiment of the present disclosure;

FIG. 10 is a diagram of a CoW unit according to an embodiment of the present disclosure;

FIG. 11 is a diagram of a CoW unit according to another embodiment of the present disclosure;

FIG. 12 is a flowchart of generating an accelerator structure according to another embodiment of the present disclosure;

FIG. 13 is a flowchart of generating a first part of a line layer according to another embodiment of the present disclosure;

FIG. 14 is a cutaway view of generating a plurality of through-silicon vias on a wafer according to another embodiment of the present disclosure;

FIG. 15 is a flowchart of generating a computing layer according to another embodiment of the present disclosure;

FIG. 16 is a cutaway view after a chip is mounted with a plurality of CoW units according to another embodiment of the present disclosure;

FIG. 17 is a cutaway view after a laminated plastic is generated according to another embodiment of the present disclosure;

FIG. 18 is a cutaway view after chemical-mechanical polishing is performed on a laminated plastic according to another embodiment of the present disclosure;

FIG. 19 is a flowchart of performing wafer testing according to another embodiment of the present disclosure;

FIG. 20 is a cutaway view after a wafer is flipped on a chip according to another embodiment of the present disclosure;

FIG. 21 is a cutaway view after chemical-mechanical polishing according to another embodiment of the present disclosure;

FIG. 22 is a cutaway view after an insulating layer is deposited according to another embodiment of the present disclosure;

FIG. 23 is a cutaway view after metal points are generated according to another embodiment of the present disclosure;

FIG. 24 is a diagram of a 5×5 CoW unit array according to an embodiment of the present disclosure;

FIG. 25 is a cutaway view after CoW dies are bonded on second glass according to another embodiment of the present disclosure;

FIG. 26 is a cutaway view after a laminated plastic is generated according to another embodiment of the present disclosure;

FIG. 27 is a cutaway view after chemical-mechanical polishing according to another embodiment of the present disclosure;

FIG. 28 is a cutaway view after the entire line layer is completed according to another embodiment of the present disclosure;

FIG. 29 is a cutaway view after a module layer is generated according to another embodiment of the present disclosure;

FIG. 30 is a cutaway view after a heat dissipation module is bonded according to another embodiment of the present disclosure;

FIG. 31 is a flowchart of generating an accelerator structure according to another embodiment of the present disclosure; and

FIG. 32 is a cutaway view after a heat dissipation module is bonded according to another embodiment of the present disclosure.

### DETAILED DESCRIPTION

Technical solutions in embodiments of the present disclosure will be described clearly and completely hereinafter with reference to drawings in the embodiments of the present disclosure. Obviously, embodiments to be described are merely some rather than all embodiments of the present disclosure. All other embodiments obtained by those skilled in the art based on the embodiments of the present disclosure without creative efforts shall fall within the protection scope of the present disclosure.

It should be understood that terms such as “first”, “second”, “third”, and “fourth” in the claims, the specification, and the drawings of the present disclosure are used for distinguishing different objects rather than describing a specific order. Terms such as “including” and “comprising” used in the specification and the claims of the present disclosure indicate the presence of a feature, an entity, a step, an operation, an element, and/or a component, but do not exclude the existence or addition of one or more other features, entities, steps, operations, elements, components, and/or collections thereof.

It should also be understood that terms used in the specification of the present disclosure are merely for a purpose of describing a particular embodiment rather than limiting the present disclosure. As being used in the specification and the claims of the present disclosure, unless the context clearly indicates otherwise, singular forms such as “a”, “an”, and “the” are intended to include plural forms. It should also be understood that a term “and/or” used in the specification and the claims of the present disclosure refers to any and all possible combinations of one or more of relevant listed items and includes these combinations.

As being used in the specification and the claims of the present disclosure, a term “if” may be interpreted as “when”, or “once” or “in response to a determination” or “in response to a case where something is detected” depending on the context.

In this specification, a wafer refers to a silicon substrate used for producing silicon semiconductor integrated circuits, which is composed of pure silicon and generally divided into 6 inches, 8 inches, 12 inches specifications, and its shape is circular. Based on the silicon substrate, various circuit component structures may be produced and then formed into integrated circuit products with specific electrical functions. A die is a small unpackaged integrated circuit body made of semiconductor material, and the established functions of the integrated circuit are carried out on this small piece of semiconductor. The die is a small square integrated circuit made on the wafer in bulk through a number of steps such as lithography and is also known as a bare die. A chip is an integrated circuit apparatus that has pins and may be electrically connected with other electronic components, which is formed by cutting down intact, stable, normal-functioning dies through testing and then packaging them.

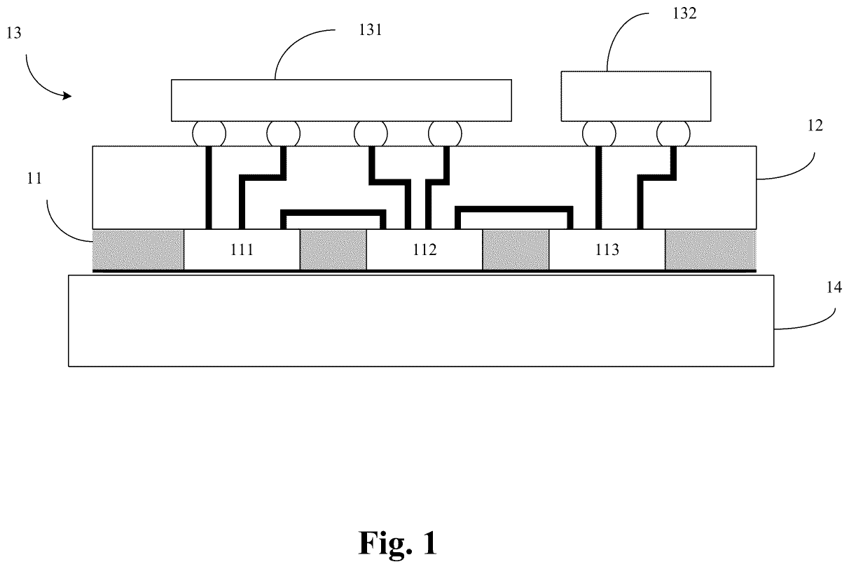

InFO_SoW technology is a wafer-level system that integrates integrated fan-out (InFO) packaging, a power module, and a heat dissipation module. FIG. 1 is a cutaway view of InFO_SoW, which includes a computing layer 11, a line layer 12, and a module layer 13. The computing layer 11 is provided with a chip array, where a processing unit 111, a processing unit 112, and a processing unit 113 are shown in the figure by example, and is configured to realize system computing functions. The line layer 12 is a re-distribution layer (RDL), and is configured to electrically connect dies of the computing layer 11 and the module layer 13. The module layer 13 is provided with a power module die group and an interface module die group. The power module die group includes a plurality of power modules 131 configured to supply power to the chip array of the computing layer 11. The interface module die group includes a plurality of interface modules 132 configured as input and output interfaces of the chip array of the computing layer 11. The power module die group and the interface module die group are soldered to the InFO wafer using ball grid array (BGA) packaging technology. A heat dissipation module 14 is assembled on the other side of the computing layer 11 and is configured to dissipate heat for the chip array of the computing layer 11.

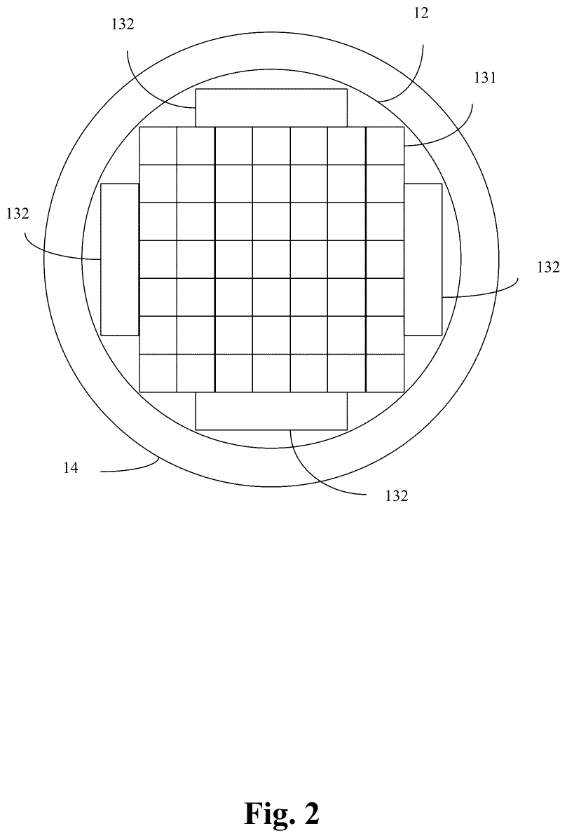

FIG. 2 is a top view of exemplary InFO_SoW. It may be seen from the figure that the power module die group consists of 7×7 power modules 131, and the interface module die group consists of four interface modules 132, which are located on the side of a power module array respectively. The line layer 12 is below the power module die group and the interface module die group, which is the InFO wafer. The chip array of the computing layer 11 is located under the line layer 12 and is obscured by the module layer 13 and the line layer 12, so the chip array of the computing layer 11 is not visible. The lowest layer is the heat dissipation module 14.

CoW is an emerging integrated production technology, which may package a plurality of chips as a single die, achieving the technical efficacy of small package size, low power consumption, and few pins. With the increasing maturity of CoW technology, more and more integrated circuits, especially those with complex operations, use the manufacturing process of the CoW technology.

One embodiment of the present disclosure shows an accelerator structure integrating a CoW unit into InFO_SoW. The CoW unit may be formed by integrating a variety of different functional dies. For convenience of illustration, the CoW unit in this embodiment includes two kinds of dies: a first die and a second die. More specifically, the first die is a system on chip (SoC), and the second die is a memory.

The system on chip refers to integrating a complete system on a single chip, and is a system or product formed by combining a plurality of integrated circuits with specific functions on a chip. System-on-integrated-chips (SoIC) refers to a multi-chip stack technology that enables bonding of CoW. The memory may be a high bandwidth memory (HBM), which is a high-performance dynamic random access memory (DRAM) based on 3D stack process and is suitable for applications with high memory bandwidth requirements, such as graphics processing units, and network switching and forwarding devices (such as routers and switches).

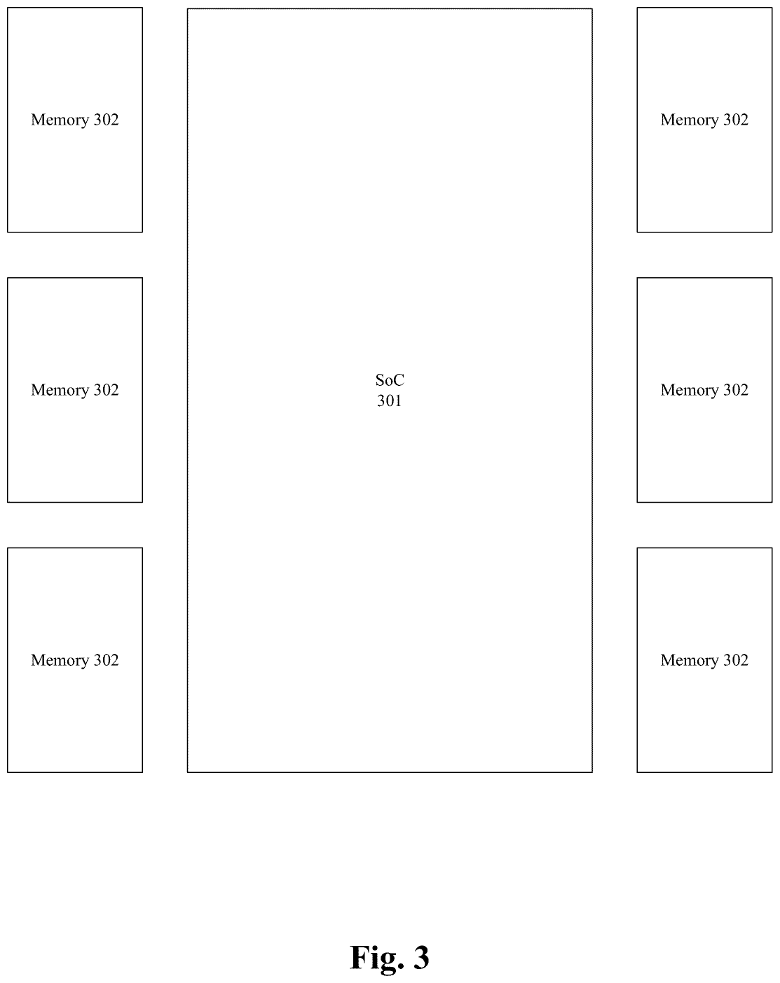

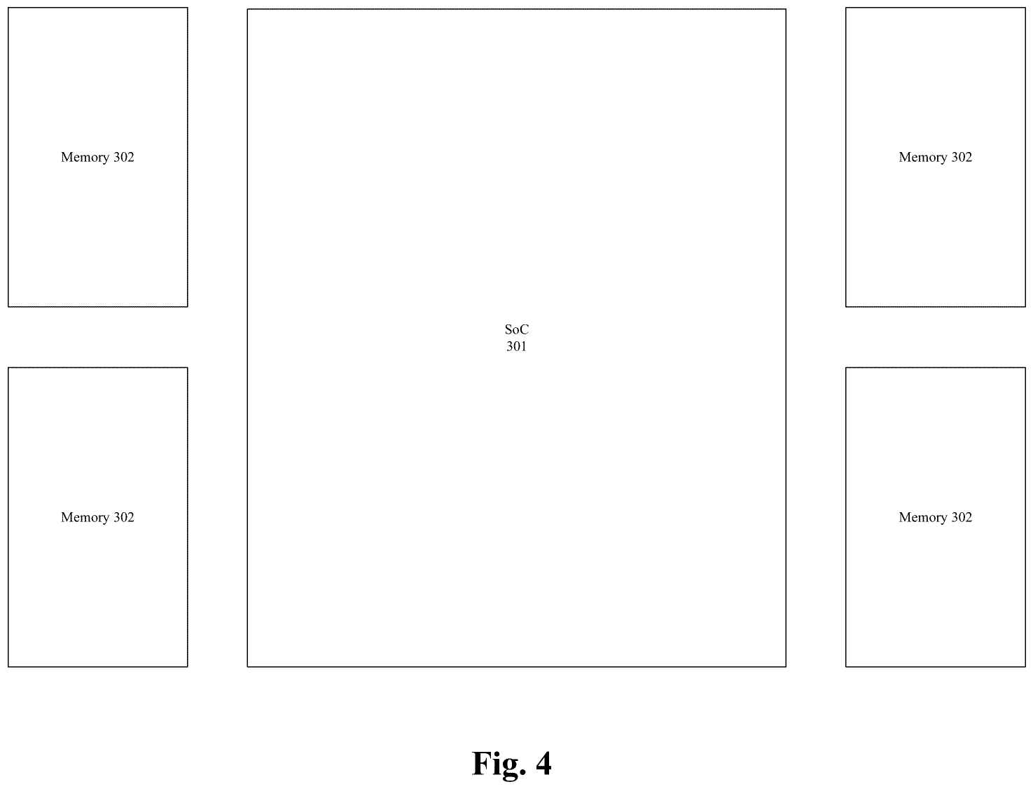

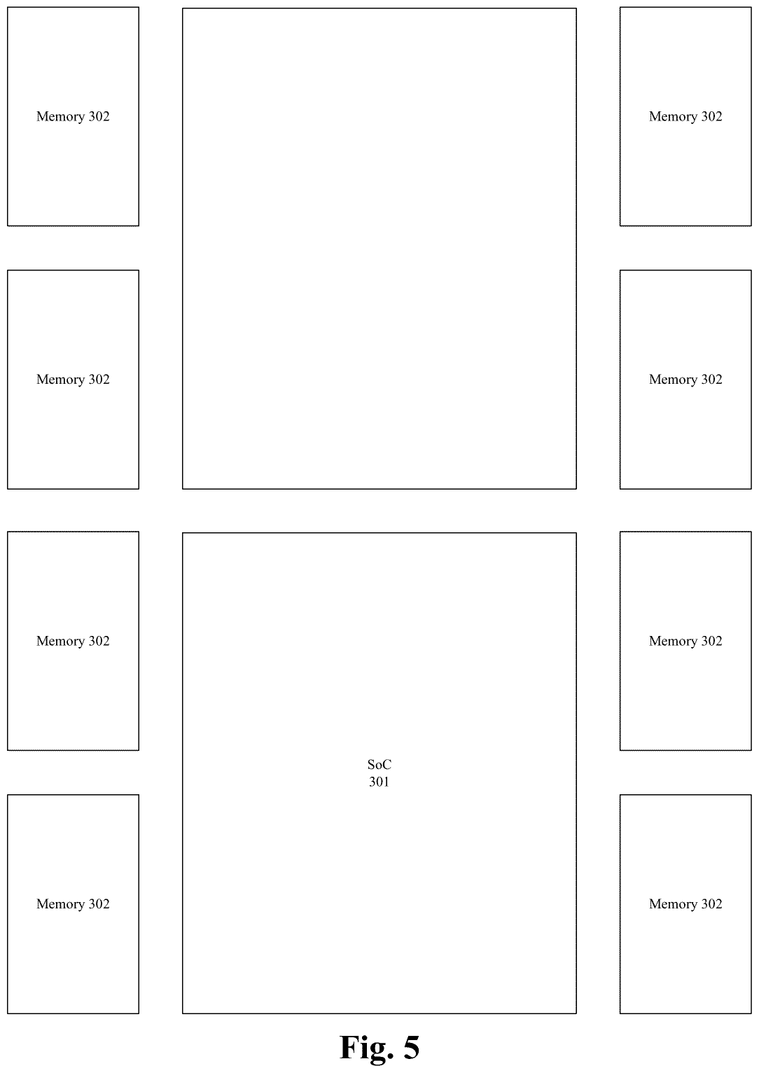

FIG. 3 is a layout diagram of the CoW unit of this embodiment. This CoW unit consists of one system on chip 301 and six memories 302. The system on chip 301 is the aforementioned system on chip and is set in the core of the CoW unit, while the memories 302 are the aforementioned high broadband memories and are arranged on both sides of the system on chip 301, with three memories 302 arranged on each side. FIG. 4 is another layout diagram of the CoW unit of this embodiment. This CoW unit consists of one system on chip 301 and four memories 302. The system on chip 301 is set in the core of the CoW unit, while the memories 302 are arranged on both sides of the system on chip 301, with two memories 302 arranged on each side. FIG. 5 is another layout diagram of the CoW unit of this embodiment. This CoW unit is arranged by two groups of CoW units as shown in FIG. 4 The system on chip and the memory are laid out in a variety of ways, the above is only an example, and the present disclosure does not limit the type, quantity and layout of the dies in the CoW unit.

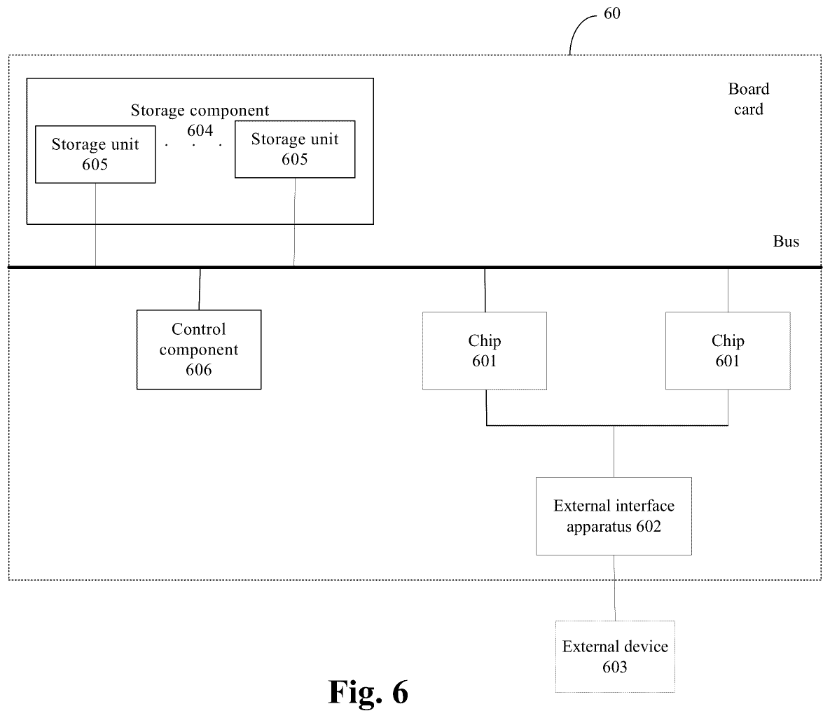

The accelerator structure of this embodiment may be assembled on a board card. FIG. 6 is a schematic structural diagram of an exemplary board card 60. As shown in FIG. 6, the board card 60 includes a chip 601, which is an accelerator structure of this embodiment, and integrates one or more integrated circuit apparatuses. The integrated circuit apparatus is an artificial intelligence computing unit, which is configured to support various deep learning algorithms and various machine learning algorithms and meet intelligent processing requirements in complex scenarios in computer vision, speech, natural language processing, data mining, and other fields. In particular, deep learning technology is widely used in the cloud intelligence field. A notable feature of cloud intelligence applications is the large amount of input data, which has high requirements for storage capacity and computing power of a platform. The board card 60 of this embodiment is suitable for cloud intelligent applications and has huge off-chip storage, huge on-chip storage, and great computing power.

The chip 601 is connected to an external device 603 through an external interface apparatus 602. The external device 603 may be, for example, a server, a computer, a camera, a monitor, a mouse, a keyboard, a network card, or a WIFI interface. To-be-processed data may be transferred from the external device 603 to the chip 601 through the external interface apparatus 602. A computing result of the chip 601 may be transferred back to the external device 603 through the external interface apparatus 602. According to different application scenarios, the external interface apparatus 602 may have different interface forms, such as a peripheral component interface express (PCIe) interface, and the like.

The board card 60 further includes a storage component 604 configured to store data. The storage component 604 includes one or more storage units 605. The storage component 604 is connected to and transfers data to a control component 606 and the chip 601 through a bus. The control component 606 in the board card 60 is configured to regulate and control a state of the chip 601. As such, in an application scenario, the control component 606 may include a micro controller unit (MCU).

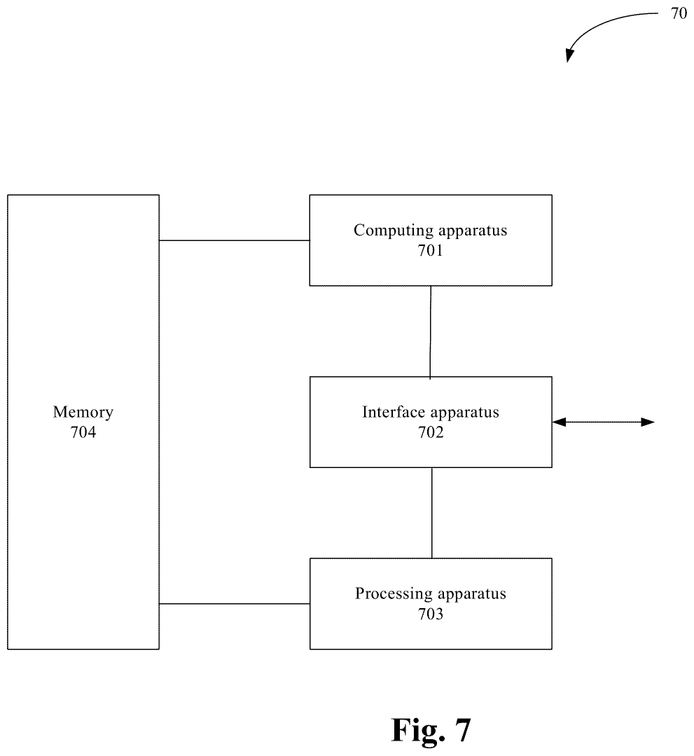

FIG. 7 is a structural diagram of an integrated circuit apparatus in the chip 601 of this embodiment. As shown in FIG. 7, an integrated circuit apparatus 70 includes a computing apparatus 701, an interface apparatus 702, a processing apparatus 703, and a memory 704.

The computing apparatus 701 is configured to perform an operation specified by a user. The computing apparatus 701 is mainly implemented as a single-core intelligent processor or a multi-core intelligent processor and is configured to perform deep learning computing or machine learning computing. The computing apparatus 701 interacts with the processing apparatus 703 to jointly complete an operation specified by a user.

The interface apparatus 702 is configured as an interface for external communication of the computing apparatus 701 and the processing unit 703.

The processing apparatus 703 serves as a general processing apparatus and performs basic controls including, but not limited to, moving data, starting and/or stopping the computing apparatus 701. According to different implementations, the processing apparatus 703 may be a CPU, a GPU, or one or more of other general and/or dedicated processors. These processors include, but are not limited to, a digital signal processor (DSP), an ASIC, a field-programmable gate array (FPGA), or other programmable logic components, discrete gate or transistor logic components, discrete hardware components, and the like. Moreover, the number of the processors may be determined according to actual requirements.

The system on chip 301 in FIGS. 3 to 5 may be the computing apparatus 701 or the processing apparatus 703, or combine the computing apparatus 701 with the processing apparatus 703. With respect to the computing apparatus 701 only, the computing apparatus 701 may be viewed as having a single-core structure or an isomorphic multi-core structure. When the computing apparatus 701 and the processing apparatus 703 are considered together, the whole structure is considered as a heterogeneous multi-core structure.

The memory 704 is configured to store to-be-processed data. The memory 704 is a double data rate (DDR) memory with a size of 16G or more than 16G generally. The memory 704 is configured to save data of the computing apparatus 701 and/or the processing apparatus 703. The memory 704 is the memory 302, which is configured to store computing data required by the system on chip 301.

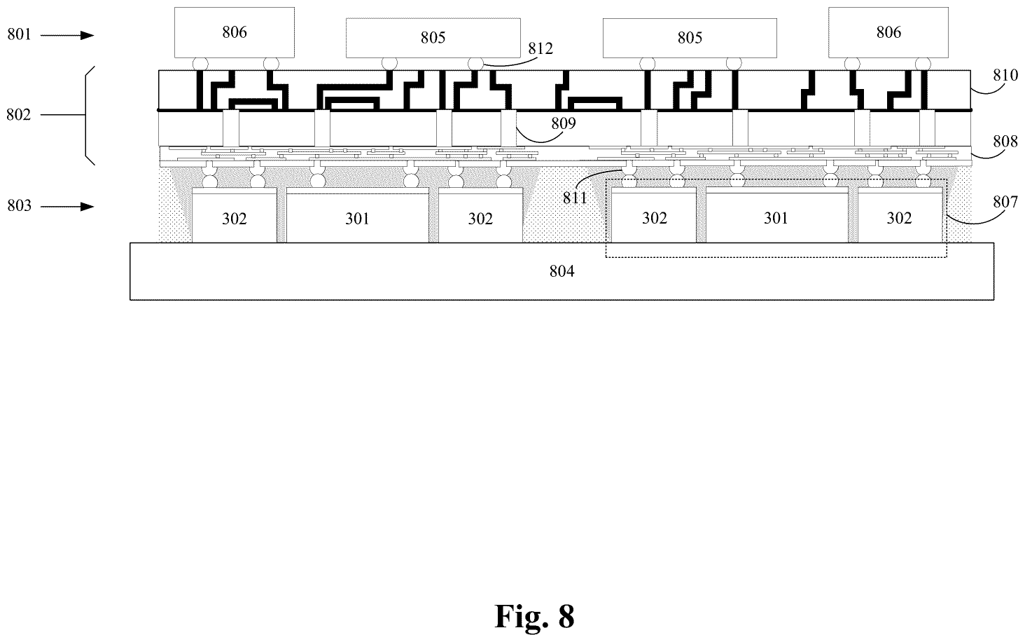

FIG. 8 is a cutaway view of an accelerator structure where CoW units are combined with InFO_SoW according to this embodiment. As shown in FIG. 8, the accelerator structure includes a module layer 801, a line layer 802, a computing layer 803, and a heat dissipation module 804.

The module layer 801 is provided with a power module die group and an interface module die group. The power module die group includes a plurality of power modules 805, which are arranged in an array as shown in FIG. 2 and supply power to CoW units of the computing layer 803. The interface module die group serves as the interface apparatus 702 and includes a plurality of interface modules 806, which are arranged around the power module die group and serves as input and output interfaces of CoW units 807 of the computing layer 803.

The line layer 802 is arranged between the computing layer 803 and the module layer 801 and includes a first re-distribution layer 808, a through-silicon via 809, and a second re-distribution layer 810 from bottom to top. The first re-distribution layer 808 electrically connects each CoW unit 807 through a bump 811. The through-silicon via 809 is arranged between the first re-distribution layer 808 and the second re-distribution layer 810 and is configured to connect the first re-distribution layer 808 and the second re-distribution layer 810. The second re-distribution layer 810 is located above the through-silicon via 809 and electrically connects the power module die group and the interface module die group in the module layer 801 through a solder ball 812.

The computing layer 803 is provided with a plurality of CoW units 807, which are also arranged in an array. As mentioned above, the CoW units in this embodiment include a first die and a second die, where the first die is the system on chip 301 and the second die is the memory 302. The system on chip 301 and the memory 302 may be arranged in the manner shown in FIG. 3 to FIG. 5 or in other ways.

The first re-distribution layer 808 is configured to electrically connect the system on chip 301 and the memory 302 in each CoW unit 807, so the system on chip 301 and the memory 302 are electrically connected to the module layer 801 through the first re-distribution layer 808, the through-silicon via 809, and the second re-distribution layer 810. When the power module die group supplies power to the CoW units 807, power signals are sent from the power modules 805 to the system on chip 301 and the memory 302 through the second re-distribution layer 810, the through-silicon via 809, and the first re-distribution layer 808. When the CoW units 807 generate computing results and want to output the computing results, the computing result are sent from the system on chip 301 or the memory 302 to the interface modules 806 through the first re-distribution layer 808, the through-silicon via 809, and the second re-distribution layer 810, and then output from the interface modules 806 outside the system. Since a data exchange capacity of an artificial intelligence chip is very large, the interface module die group of this embodiment is an optical module, which may be specifically an optical fiber module to convert an electrical signal from the system on chip 301 or the memory 302 into an optical signal for output. When the CoW units 807 need to load data outside the system, the data is converted from an optical signal to an electrical signal by the interface modules 806 and is stored in the memory 302 through the second re-distribution layer 810, the through-silicon via 809, and the first re-distribution layer 808.

In addition, each CoW unit 807 of this embodiment may be electrically connected to another adjacent CoW unit via the first re-distribution layer 808, the through-silicon via 809, and the second re-distribution layer 810 to exchange data with each other, so that all CoW units 807 may collaborate together to form an accelerator with great computing power.

The heat dissipation module 804 is located under the computing layer 803 and is bonded to the CoW units 807. The heat dissipation module 804 is configured to dissipate heat for all CoW units 807 in the computing layer 803. The heat dissipation module 804 may be a water-cooled backplane. The backplane has layers of microchannels. Coolant flows through these channels to carry away heat by a water pump; or by cutting gallium nitride (GaN) into the silicon below, original gaps in the GaN layer are filled with copper as the channels are widened during etching, where under these channels are designed coolant pipelines, and copper helps to conduct heat to the coolant.

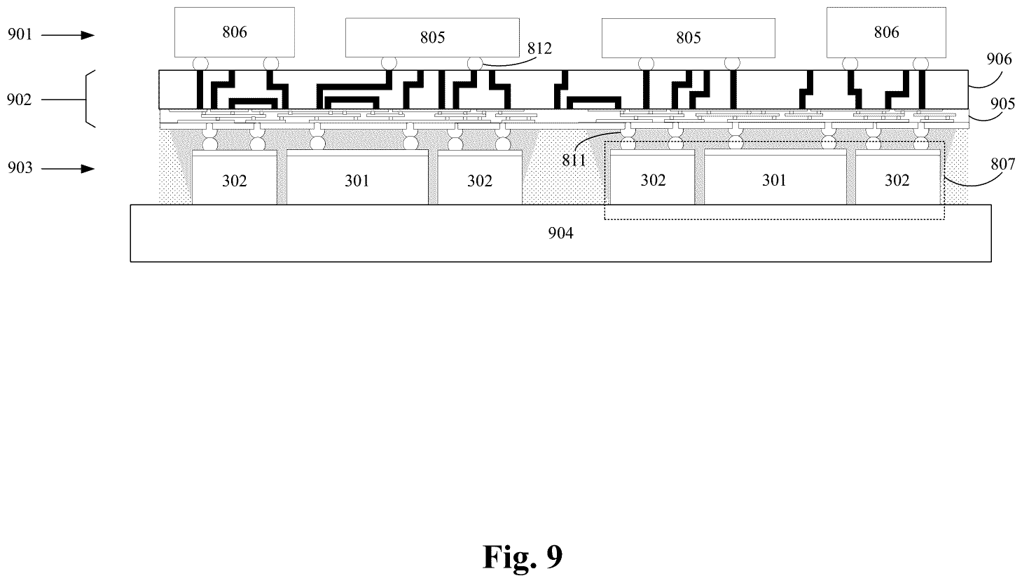

FIG. 9 is a cutaway view of an accelerator structure where CoW units are combined with InFO_SoW according to an embodiment of the present disclosure. As shown in FIG. 9, this accelerator structure includes a module layer 901, a line layer 902, a computing layer 903, and a heat dissipation module 904, where structures of the module layer 901, the computing layer 903, and the heat dissipation module 904 are the same as structures of corresponding components in the embodiment of FIG. 8, so related descriptions will not be repeated.

The line layer 902 is arranged between the computing layer 903 and the module layer 901, and only includes a first re-distribution layer 905 and a second re-distribution layer 906. The structure of the first re-distribution layer 905 is the same as that of the first re-distribution layer 808, and the structure of the second re-distribution layer 906 is the same as that of the second re-distribution layer 810. The first re-distribution layer 905 is directly connected to the second re-distribution layer 906. Without the use of through-silicon via for connection, such a line layer 902 may achieve the same effect as the line layer 802, and save the process of generating the through-silicon via 809.

In addition to being a single-layer die structure as described in the preceding embodiment, the CoW unit of the present disclosure may also be a multi-layer vertically stacked die group; in other words, the CoW unit of the present disclosure includes a first die group and a second die group, where in addition to being single-layer die structures, the first die group and the second die group may also be multi-layer vertically stacked structures. The multi-layer vertically stacked structure will be described in the following.

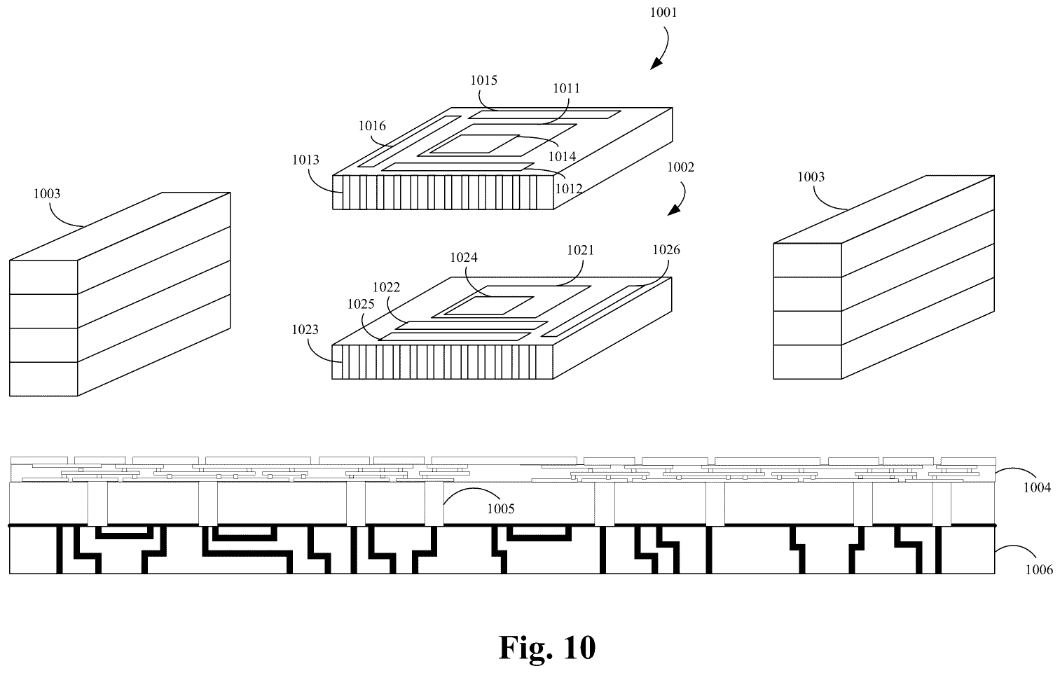

Another embodiment of the present disclosure also shows an accelerator structure where CoW units are combined with InFO_SoW. Different from the above embodiment, the first die group of the CoW unit in this embodiment includes a first core layer and a second core layer that are stacked vertically, and the second die group is a memory. FIG. 10 is a schematic diagram of the CoW unit of this embodiment. It should be noted that for convenience of explanation, the view of this diagram is that the line layer is below the computing layer, instead of the line layer being above the computing layer as shown in FIG. 8 or FIG. 9.

The first die group includes a first core layer 1001 and a second core layer 1002. In fact, the first core layer 1001 and the second core layer 1002 are stacked vertically in one piece. The first core layer 1001 and the second core layer 1002 in FIG. 10 are visually separated from each other and shown in this way only for convenience of explanation. The CoW unit of this embodiment includes two second die groups, which are single-die memories 1003, and more specifically, are high broadband memories.

The first core layer 1001 includes a first computing area 1011, a first die-to-die area 1012, and a first through-silicon via 1013. The first computing area 1011 is provided with a first computing circuit, which is configured to realize functions of the computing apparatus 701. The first die-to-die area 1012 is provided with a first transceiver circuit, which is configured as a die-to-die interface of the first computing circuit. The first through-silicon via 1013 is configured to realize the electrical interconnection of stacked dies in 3D integrated circuits. The second core layer 1002 includes a second computing area 1021, a second die-to-die area 1022, and a second through-silicon via 1023. The second computing area 1021 is provided with a second computing circuit, which is configured to realize functions of the processing apparatus 703. The second die-to-die area 1022 is provided with a second transceiver circuit, which is configured as a die-to-die interface of the second computing circuit. The second through-silicon via 1023 is also configured to realize the electrical interconnection of stacked dies in 3D integrated circuits.

In this embodiment, the first computing area 1011 is also provided with a memory 1014, which is configured to temporarily store a computing result of the first computing circuit, and the second computing area 1021 is also provided with a memory 1024, which is configured to temporarily store a computing result of the second computing circuit. The memory 1014 is directly set in the first computing area 1011, and the memory 1024 is also directly set in the second computing area 1021. Without the need for transmitting data through intermediary layers, the data transmission rate is fast, but the storage space is limited.

The first core layer 1001 also includes an input and output area 1015 and a physical area 1016, and the second core layer 1002 also includes an input and output area 1025 and a physical area 1026. The input and output area 1015 is provided with an input and output circuit, which is configured as an interface of the first core layer 1001 for external communication. The input and output area 1025 is provided with an input and output circuit, which is configured as an interface of the second core layer 1002 for external communication. The physical area 1016 is provided with a physical access circuit, which is configured as an interface for the first core layer 1001 to access an off-chip memory. The physical area 1026 is provided with a physical access circuit, which is configured as an interface for the second core layer 1002 to access an off-chip memory.

When the computing apparatus 701 intends to exchange data with the processing apparatus 703, the first computing circuit and the second computing circuit transmit data between layers through the first transceiver circuit and the second transceiver circuit. Specifically, the data reaches the processing apparatus 703 through the following path: the first computing circuit of the first computing area 1011→the first transceiver circuit of the first die-to-die area 1012→the first through-silicon via 1013→the second transceiver circuit of the second die-to-die area 1022→the second computing circuit of the second computing area 1021. When the processing apparatus 703 intends to transmit data to the computing apparatus 701, the data arrives through the following path: the second computing circuit of the second computing area 1021→the second transceiver circuit of the second die-to-die area 1022→the first through-silicon via 1013→the first transceiver circuit of the first die-to-die area 1012→the first computing circuit of the first computing area 1011.

When the computing apparatus 701 intends to store data to the memory 1003, a computing result of the computing apparatus 701 is stored to the memory 1003 through the physical area 1016, and the memory area 1014 transmits the data to the memory 1003 through the physical access circuit. Specifically, the data reaches the memory 1003 through the following path: the physical access circuit of the physical area 1016→the first through-silicon via 1013→the second through-silicon via 1023→a first re-distribution layer 1004 of the line layer. When the memory 1003 intends to transmit data to the memory area 1014 for processing by the computing apparatus 701, the data reaches the memory area 1014 by reversing the path described above. It should be noted that some specific through-silicon vias in the first through-silicon via 1013 and the second through-silicon via 1023 are specifically designed to electrically conduct data of the physical access circuit.

When the processing apparatus 703 intends to store data to the memory 1003, a computing result of the processing apparatus 703 is stored to the memory 1003 through the physical area 1026, and the memory area 1024 transmits the data to the memory 1003 through the physical access circuit. Specifically, the data reaches the memory 1003 through the following path: the physical access circuit of the physical area 1026→the second through-silicon via 1023→the first re-distribution layer 1004 of the line layer. When the memory 1003 intends to transmit data to the memory area 1024 for processing by the processing apparatus 703, the data reaches the memory area 1024 by reversing the path described above.

When the computing result of the computing apparatus 701 needs to be exchanged with a first die group of another CoW unit in the computing layer, the memory area 1014 transmits the data to the first die group of another CoW unit through the input and output circuit. Specifically, the data reaches another CoW unit through the following path: the input and output circuit of the input and output area 1015→the first through-silicon via 1013→the second through-silicon via 1023→the first re-distribution layer 1004 of the line layer→a through-silicon via 1005 of the line layer→a second re-distribution layer 1006 of the line layer→the through-silicon via 1005 of the line layer→the first re-distribution layer 1004 of the line layer. When the first die group of another CoW unit intends to transmit data to the memory area 1014, the data reaches the memory area 1014 by reversing the path described above. It should be noted that some specific through-silicon vias in the first through-silicon via 1013 and the second through-silicon via 1023 are specifically designed to electrically conduct data of the input and output circuit.

When the computing result of the processing apparatus 703 needs to be exchanged with a first die group of another CoW unit, the data in the memory area 1024 reaches the first die group of another CoW unit through the following path: the input and output circuit of the input and output area 1025→the second through-silicon via 1023→the first re-distribution layer 1004 of the line layer→the through-silicon via 1005 of the line layer→the second re-distribution layer 1006 of the line layer→the through-silicon via 1005 of the line layer→the first re-distribution layer 1004 of the line layer. When the first die group of another CoW unit intends to transmit data to the memory area 1024, the data reaches the memory area 1024 by reversing the path described above.

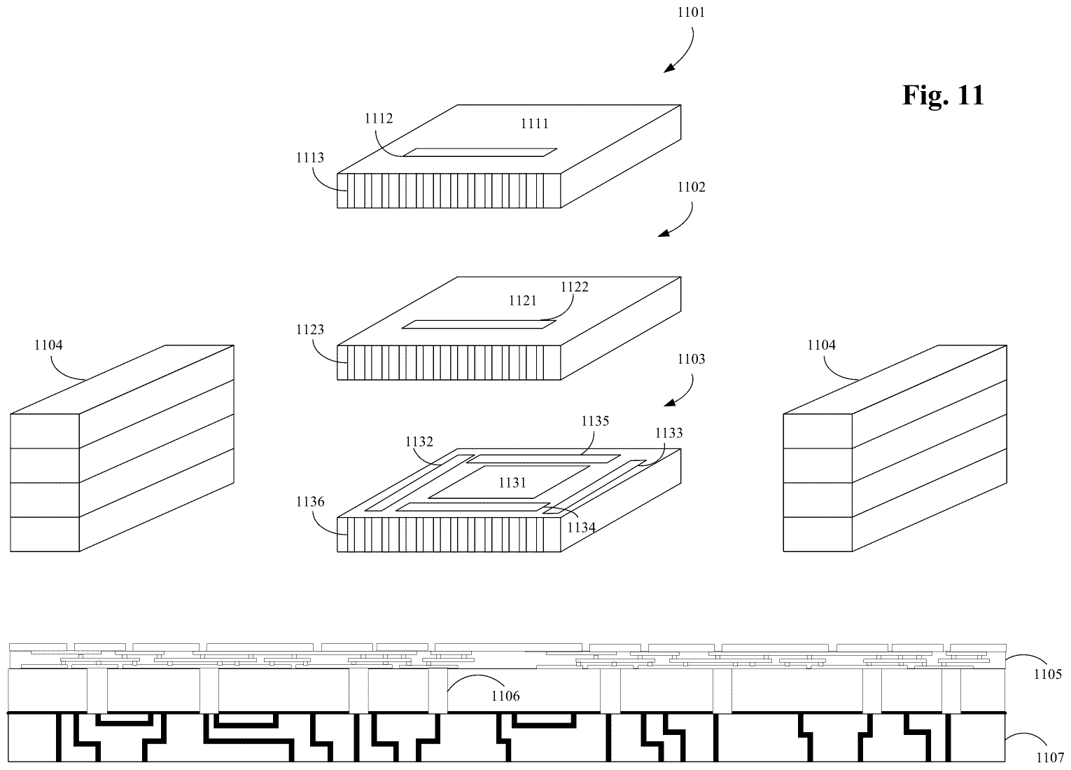

Another embodiment of the present disclosure also shows an accelerator structure where CoW units are combined with InFO_SoW. The first die group of the computing layer in this embodiment includes a first core layer, a second core layer, and a memory layer that are stacked vertically, and the second die group is a memory. FIG. 11 is a diagram of the CoW unit of this embodiment.

The first die group of this embodiment includes a first core layer 1101, a second core layer 1102, and an on-chip memory layer 1103. In fact, the first core layer 1101, the second core layer 1102, and the on-chip memory layer 1103 are stacked vertically from top to bottom in sequence in one piece. The layers in FIG. 11 are visually separated from each other and shown in this way only for convenience of explanation. The CoW unit of this embodiment includes two second die groups, which are single-die memories 1104, and more specifically, are high broadband memories.

The first core layer 1101 includes a first computing area 1111, which realizes functions of the computing apparatus 701. The first computing area 1111 covers a logic layer of the first core layer 1101, which is a top side of the first core layer 1101 in the figure. The first core layer 1101 also includes a first die-to-die area 1112 and a first through-silicon via 1113 in a specific area. The second core layer 1102 includes a second computing area 1121, which realizes functions of the processing apparatus 703. The second computing area 1121 covers a logic layer of the second core layer 1102, which is a top side of the second core layer 1102 in the figure. The second core layer 1102 also includes a second die-to-die area 1122 and a second through-silicon via 1123 in a specific area. The first die-to-die area 1112 is relative to the second die-to-die area 1122 in terms of position. Functions and effects of the first die-to-die area 1112 and the second die-to-die area 1122 are the same as those of the aforementioned embodiments, so related descriptions will not be repeated.

The on-chip memory layer 1103 includes a memory area 1131, a first input and output area 1132, a second input and output area 1133, a first physical area 1134, a second physical area 1135, and a third through-silicon via 1136. The memory area 1131 is provided with a storage unit, which is configured to temporarily store a computing result of a first computing circuit or a second computing circuit. The first input and output area 1132 is provided with a first input and output circuit, which is configured as an interface of the first computing circuit for external communication. The second input and output area 1133 is provided with a second input and output circuit, which is configured as an interface of the second computing circuit for external communication. The first physical area 1134 is provided with a first physical access circuit, which is configured to send a computing result of the first computing circuit stored in the memory area 1131 to the memory 1104. The second physical area 1135 is provided with a second physical access circuit, which is configured to send a computing result of the second computing circuit stored in the memory area 1131 to the memory 1104. The third through-silicon via 1136 is spread throughout the on-chip memory layer 1103, and is shown on only one side for the sake of illustration.

When the computing apparatus 701 intends to exchange data with the processing apparatus 703, the first computing circuit and the second computing circuit transmit data between layers through a first transceiver circuit and a second transceiver circuit. Specifically, the data reaches the processing apparatus 703 through the following path: the first computing circuit of the first computing area 1111→a first transceiver circuit of the first die-to-die area 1112→the first through-silicon via 1113→a second transceiver circuit of the second die-to-die area 1122→the second computing circuit of the second computing area 1121. When the processing apparatus 703 intends to transmit data to the computing apparatus 701, the data reaches the computing apparatus 701 by reversing the path described above. It should be noted that some specific through-silicon vias in the first through-silicon via 1113 are specifically designed to electrically connect the first transceiver circuit and the second transceiver circuit.

When the computing result (temporarily stored in the memory area 1131) of the computing apparatus 701 needs to be stored in the memory 1104, the memory area 1131 transmits the data to the memory 1104 through the first physical access circuit. Specifically, the data reaches the memory 1104 through the following path: the first physical access circuit of the first physical area 1134→the third through-silicon via 1136→a first re-distribution layer 1105 of the line layer. When the memory 1104 intends to transmit data to the memory area 1131 for processing by the computing apparatus 701, the data reaches the memory area 1131 by reversing the path described above.

When the computing result (temporarily stored in the memory area 1131) of the processing apparatus 703 needs to be stored in the memory 1104, the memory area 1131 transmits the data to the memory 1104 through the second physical access circuit. Specifically, the data reaches the memory 1104 through the following path: the second physical access circuit of the second physical area 1135→the third through-silicon via 1136→the first re-distribution layer 1105 of the line layer. When the memory 1104 intends to transmit data to the memory area 1131 for processing by the processing apparatus 703, the data reaches the memory area 1131 by reversing the path described above.

It should be noted that some specific through-silicon vias in the third through-silicon via 1136 are specifically designed to electrically conduct data of the first physical access circuit and the second physical access circuit.

When the computing result of the computing apparatus 701 needs to be exchanged with a first die group of another CoW unit, the memory area 1131 transmits the data to the first die group of another CoW unit through the first input and output circuit. Specifically, the data reaches the first die group of another CoW unit through the following path: the input and output circuit of the first input and output area 1132→the third through-silicon via 1136→the first re-distribution layer 1105 of the line layer→a through-silicon via 1106 of the line layer→a second re-distribution layer 1107 of the line layer→the through-silicon via 1106 of the line layer→the first re-distribution layer 1105 of the line layer. When the first die group of another CoW unit intends to exchange data with the computing apparatus 701, the data reaches the memory area 1131 by reversing the path described above.

When the computing result of the processing apparatus 703 needs to be exchanged with a first die group of another CoW unit, the memory area 1131 transmits the data to the first die group of another CoW unit through the second input and output circuit. Specifically, the data reaches the first die group of another CoW unit through the following path: the input and output circuit of the second input and output area 1133→the third through-silicon via 1136→the first re-distribution layer 1105 of the line layer→the through-silicon via 1106 of the line layer→the second re-distribution layer 1107 of the line layer→the through-silicon via 1106 of the line layer→the first re-distribution layer 1105 of the line layer. When the first die group of another CoW unit intends to exchange data with the processing apparatus 703, the data reaches the memory area 1131 by reversing the path described above.

It should be noted that some specific through-silicon vias in the third through-silicon via 1136 are specifically designed to electrically conduct data of the first input and output circuit and the second input and output circuit.

The present disclosure does not limit the number and function of vertically stacked dies in the first die group and the second die group. For example, the first die group may also include a first core layer, a first memory layer, a second core layer, and a second memory layer that are stacked from top to bottom; or the first die group includes a first core layer, a first memory layer, a second core layer, a second memory layer, a third memory layer, and a fourth memory layer that are stacked from top to bottom. On the basis of the foregoing embodiments, electrical relations of various combinations of the first die group and the second die group may be known to those skilled in the art without creative effort, and are therefore not detailed.

It may be seen from the above description that the system on chip of the present disclosure may be connected vertically with other system on chips in the first die group, and may also be connected horizontally with system on chips of first die groups in other CoW units, thus forming a three-dimensional computing processor core.

The CoW units of the accelerator structure in the above embodiments are arranged in an array, and the InFO_SoW technology enables the CoW units to efficiently cooperate with their surrounding CoW units. A task computed by a neural network model is generally processed by such an accelerator structure. The task is first cut into a plurality of subtasks, and each first die group assigns one subtask respectively. During subtask assignment, a CoW unit near the center of the array may be planned to transmit an intermediate result to neighboring CoW units. The intermediate result is accumulated successively until the computing result of the entire task is computed by the outermost CoW unit, and the computing result is directly output through the interface module of the interface module die group. As shown in FIG. 2, since an interface module 132 is located on the outside of the accelerator structure, when the intermediate results are accumulated from the center of the array to the surrounding, the outermost CoW unit will finally obtain the computing result of the task, and the computing result is directly output through the adjacent interface module 132. Such a task arrangement makes a transmission path of the data more streamlined and efficient.

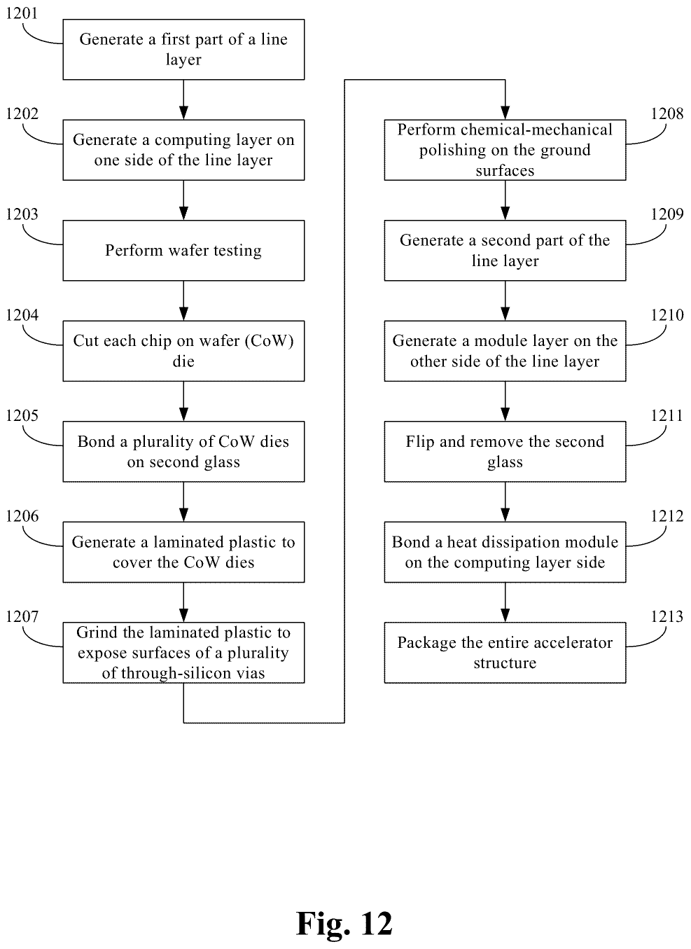

Another embodiment of the present disclosure is a method for generating an accelerator structure, more specifically a method for generating the accelerator structure of the aforementioned embodiments. In this embodiment, a line layer is generated first. Next, a computing layer is generated on one side of the line layer, where the computing layer is provided with a plurality of CoW units, each of which includes a first die group and a second die group. Moreover, a module layer is generated on the other side of the line layer, where the module layer is provided with a power module die group and an interface module die group. The power module die group supplies power to the first die group and the second die group through the line layer, and the first die group and the second die group output a computing result through the interface module die group via the line layer. FIG. 12 is a flowchart of this embodiment.

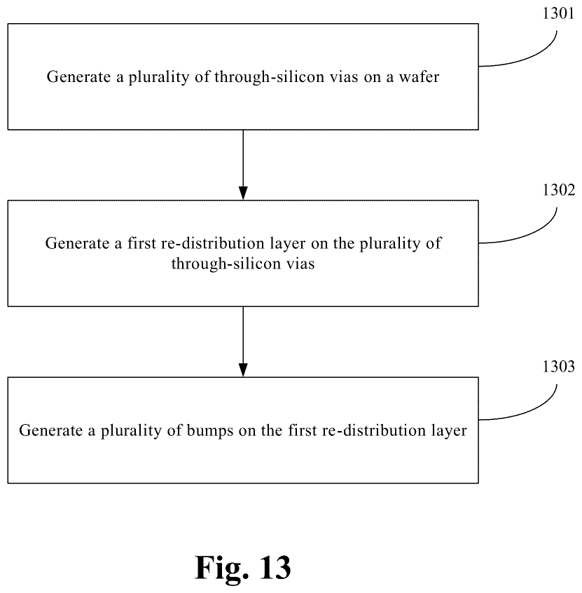

In step 1201, a first part of a line layer is generated; in other words, the first re-distribution layer 808 and the through-silicon via 809 in the line layer 802 in FIG. 8 are generated on the InFO wafer. This step is further refined into the flowchart shown in FIG. 13.

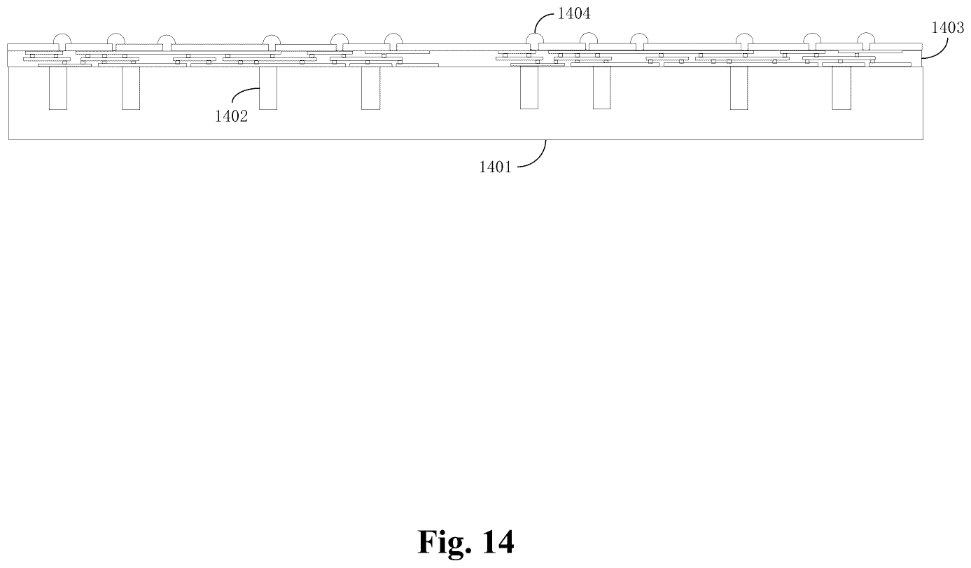

In step 1301, referring to FIG. 14, a plurality of through-silicon vias 1402 are generated on a wafer 1401. Through-silicon via technology is a high-density packaging technology. Specifically, by filling electrically conductive materials such as copper, tungsten, and polysilicon, the vertical electrical interconnection of the through-silicon vias 1402 is realized, thus reducing the interconnection length, reducing the signal delay, achieving low power consumption, high-speed communication, and increased broadband between chips, and realizing the miniaturization of device integration.

In step 1302, a first re-distribution layer 1403 is generated on one side of the plurality of through-silicon vias 1402. The first re-distribution layer 1403 makes the die be applied to different packaging forms by performing the wafer-level metal wiring process on the contact of the die (the output/input end of the die) and changing the position of the contact. In short, a metal layer and a dielectric layer are deposited on the wafer 1401, and a corresponding three-dimensional metal wiring pattern is formed, which is used to rearrange the output/input end of the die to conduct electrical signal transmission, making the die layout more flexible. In the design of the first re-distribution layer 1403, it is necessary to increase a through-silicon via in the overlapping position of the crisscrossing metal wiring with the same electrical characteristics in the adjacent two layers to ensure the electrical connection between the upper and lower layers, so the first re-distribution layer 1403 realizes the electrical connection among a plurality of dies by a three-dimensional conduction structure, thereby reducing the layout area.

In step 1303, a plurality of bumps 1404 are generated on the first re-distribution layer 1403. In practice, the bumps 1404 are solder balls, and common solder ball processes include: evaporation, electroplating, screen printing, or needle depositing. In this embodiment, solder balls are not directly connected to metal wires in the first re-distribution layer 1403, but are bridled under bump metallization (UBM) to improve adhesion, where the UBM is usually realized by sputtering or electroplating. So far, the first re-distribution layer 808 and the through-silicon via 809 in the line layer 802 in FIG. 8 have been generated.

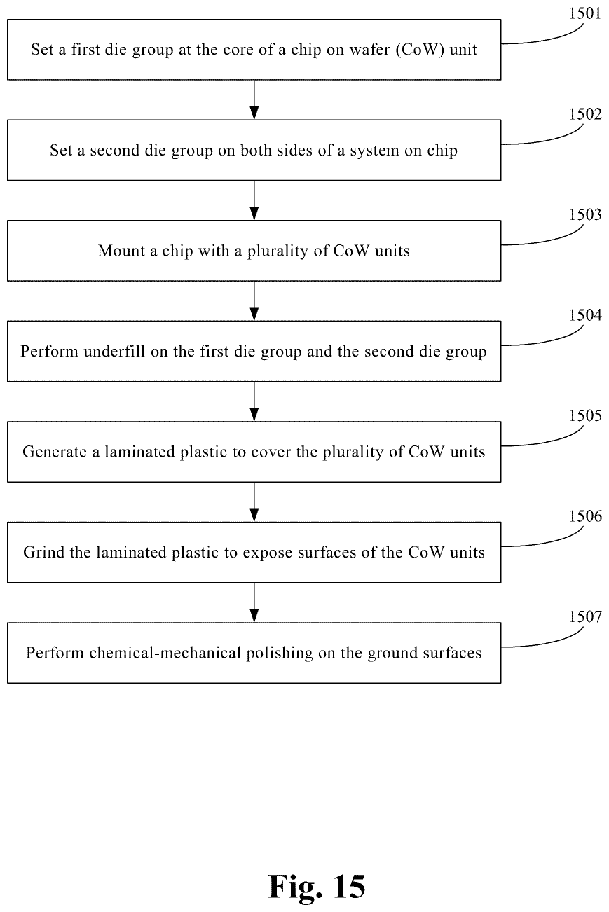

Going back to FIG. 12, in step 1202, the computing layer 803 of FIG. 8 is generated on one side of the line layer. As described in the preceding embodiment, the computing layer is provided with a plurality of CoW units, each of which includes a first die group and a second die group. This step is further refined into the flowchart shown in FIG. 15.

In step 1501, a first die group (a system on chip) is set at the core of a CoW unit. In step 1502, a second die group (a memory) is set on both sides of the system on chip. These two steps are used to realize the layout of the CoW unit as shown in FIG. 3 to FIG. 5. Specifically, the CoW unit of this embodiment includes the first die group and the second die group, where the first die group is the system on chip 301, and the second die group is the memory 302, where the memory 302 is a high broadband memory.

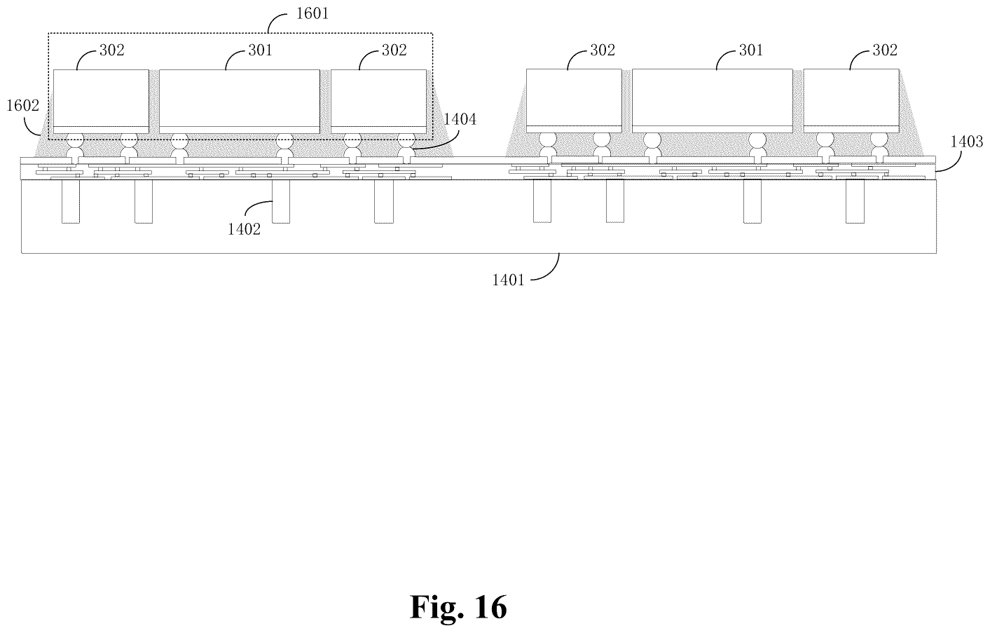

In step 1503, a chip is mounted with a plurality of CoW units, where the first die group and the second die group are electrically contacted with the plurality of bumps 1404 respectively. As shown in FIG. 16, a CoW unit 1601 includes the system on chip 301 and the memory 302, the chip is mounted on the first re-distribution layer 1403, and the contacts of the system on chip 301 and the memory 302 are electrically contacted with the bumps 1404. The number of CoW units 1601 mounted on the chip is determined by a size of the wafer 1401.

In step 1504, underfill is performed on the first die group and the second die group. As shown in FIG. 16, the underfill is mainly by non-contact jet dispensing to produce sealant 1602. The sealant 1602 provides a sealing effect for the contacts of the first die group and the second die group and the bumps 1404, thus avoiding the electrical interference caused by the contact with impurities for the contacts and the bumps 1404. Such a structure has better reliability.

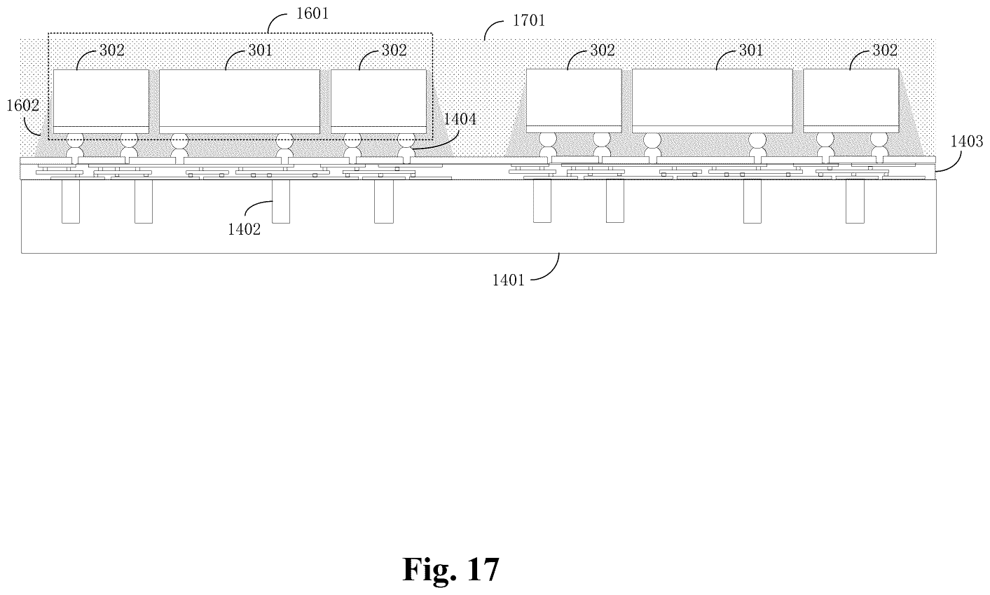

In step 1505, a laminated plastic is generated to cover a plurality of CoW units 1601. FIG. 17 is a structural diagram after a laminated plastic is generated. As shown in FIG. 17, a laminated plastic 1701 covers all CoW units 1601 to protect the overall structure.

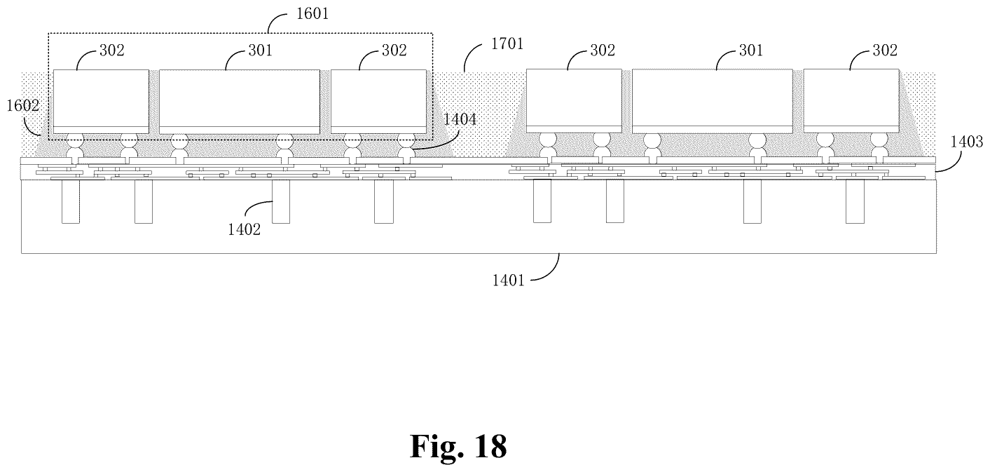

In step 1506, the laminated plastic is ground to expose surfaces of the plurality of CoW units 1601. In step 1507, chemical-mechanical polishing (CMP) is performed on the ground surfaces. As shown in FIG. 18, the surfaces (top surfaces) of the CoW units 1601 are exposed to air after the chemical-mechanical polishing of the laminated plastic 1701. So far, the computing layer has been generated.

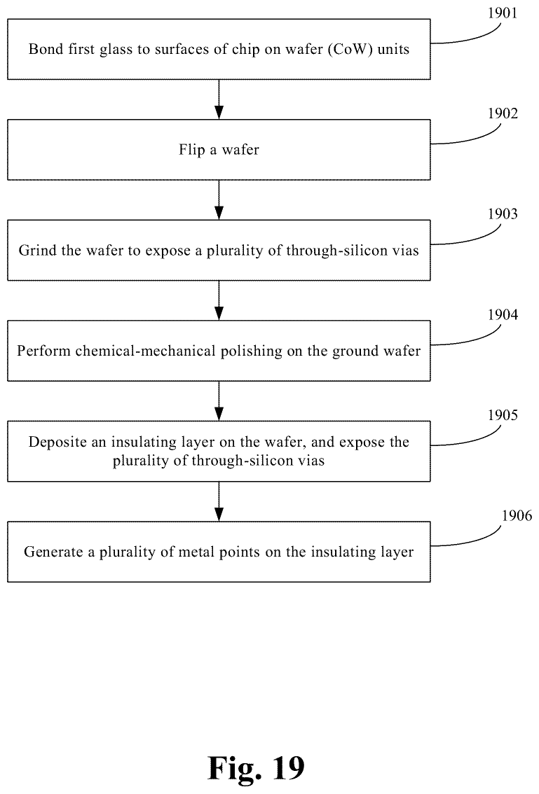

Going back to FIG. 12, then, the step 1203 is executed to perform wafer testing. This step is further refined into the flowchart shown in FIG. 19.

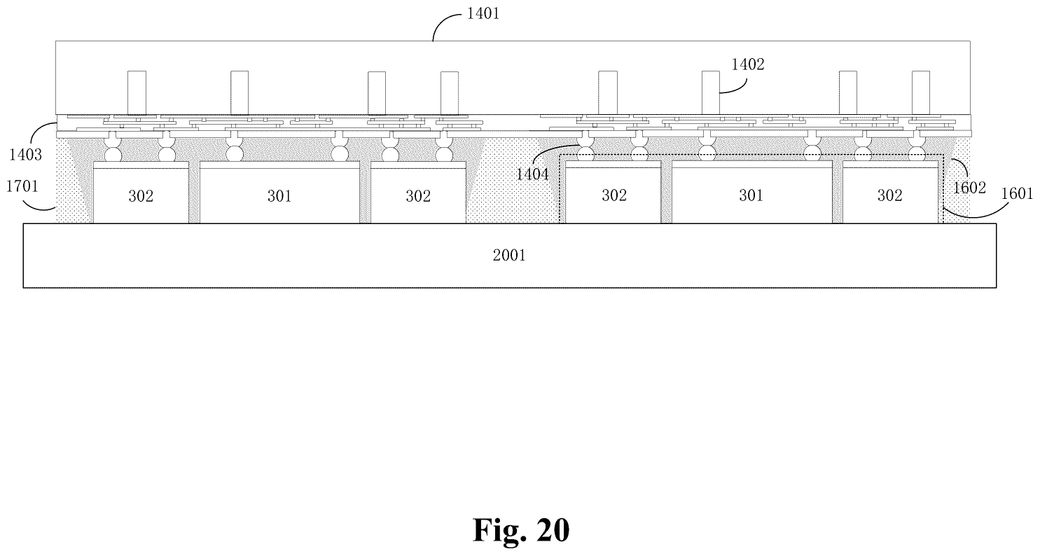

In step 1901, first glass is bonded on the surfaces of the CoW units 1601. In step 1902, the wafer 1401 is flipped, so that the first glass is located below the wafer 1401. FIG. 20 shows a structural diagram after flipping. As shown in FIG. 20, first glass 2001 is bonded on the surfaces of the CoW units 1601. After the wafer 1401 is flipped, the first glass is used as a base to support the wafer 1401 and various semiconductor structures generated based on the wafer 1401, including the CoW units 1601, so as to facilitate subsequent processing of the bottom (above the wafer 1401 in FIG. 20) of the wafer 1401.

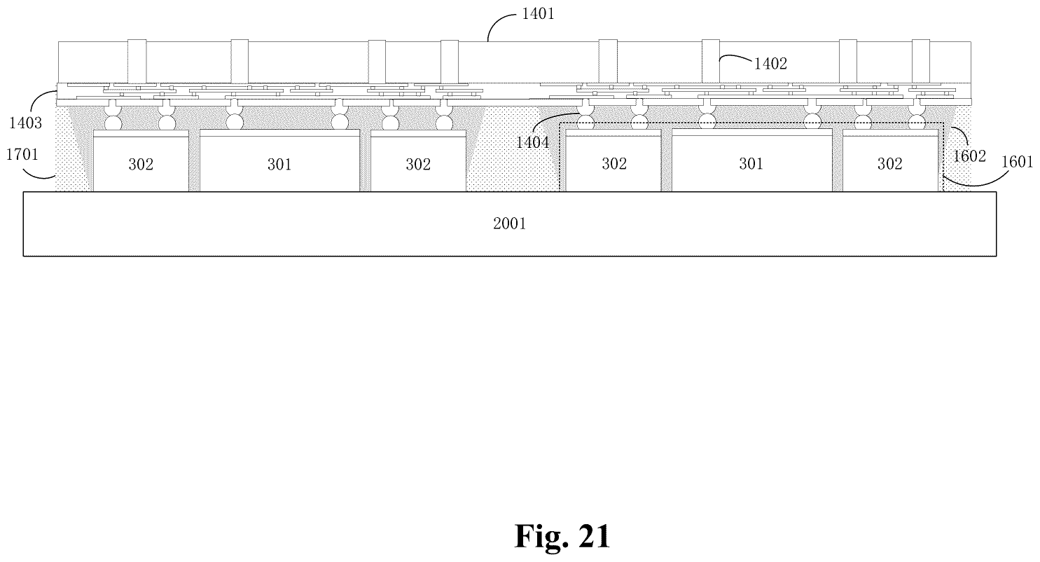

In step 1903, the wafer 1401 is ground to expose a plurality of through-silicon vias 1402. In step 1904, chemical-mechanical polishing is performed on the ground wafer. FIG. 21 is a cutaway view after chemical-mechanical polishing. As shown in FIG. 21, top surfaces of the through-silicon vias 1402 are exposed outside the wafer 1401.

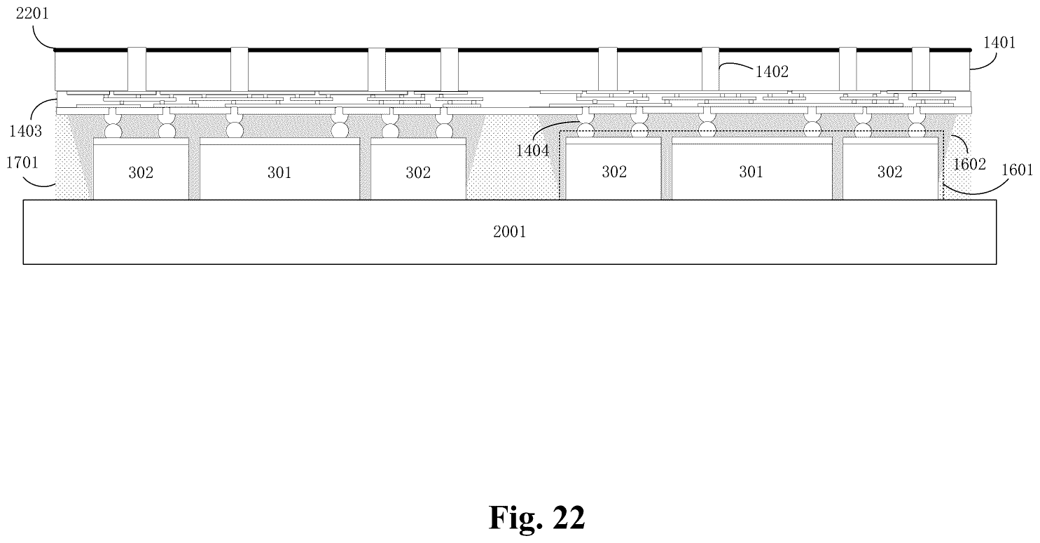

In step 1905, an insulating layer is deposited on the wafer 1401, and the plurality of through-silicon vias 1402 are exposed. In this step, the top surfaces of the through-silicon vias 1402 are covered by a light mask, and then the insulating layer is deposited on the top surface, where the material of the insulating layer may be silicon nitride. FIG. 22 is a structural diagram after an insulating layer is deposited. As shown in FIG. 22, since the light mask covers the top surfaces of the through-silicon vias 1402, the top surfaces of the through-silicon vias 1402 remains exposed to the air after an insulating layer 2201 is deposited.

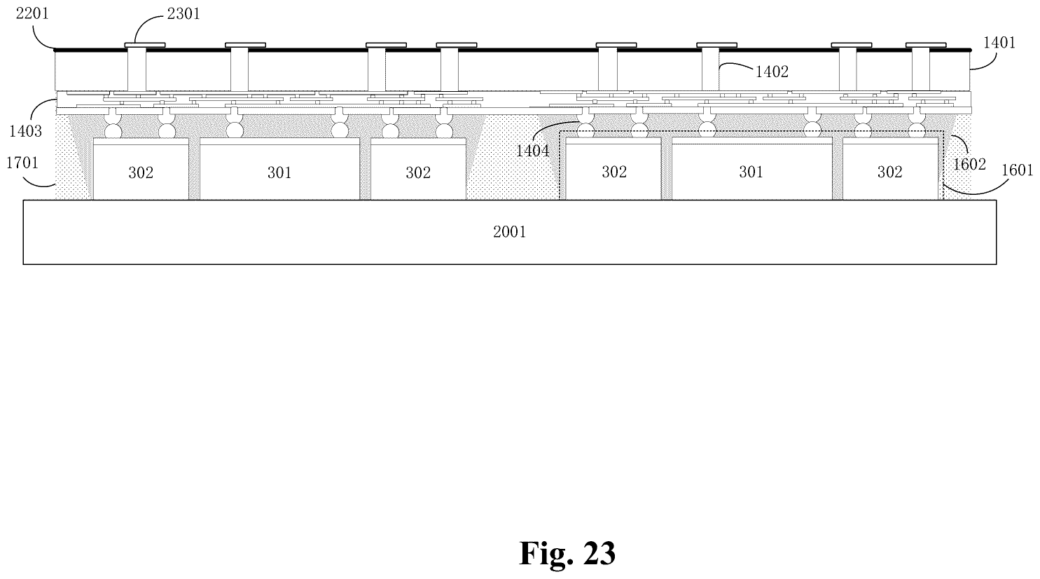

In step 1906, a plurality of metal points are generated on the insulating layer 2201. These metal points are appropriately electrically contacted with at least one of the plurality of through-silicon vias 1402 to serve as wafer testing points for electrical contact of a probe. FIG. 23 is a structural diagram after metal points 2301 are generated. As shown in FIG. 23, each through-silicon via 1402 is connected to one metal point 2301 to serve as a wafer testing point for probe contact of the wafer testing.

In this embodiment, testable content of the wafer testing includes scan testing, boundary scan testing, memory testing, direct current (DC)/alternating current (AC) testing, radio frequency (RF) testing, and other function testing. The scan testing is used to detect logical functions of a first die group and a second die group. The boundary scan testing is used to detect pin functions of the first die group and the second die group. The memory testing is used to test read and write and storage functions of various types of storage units (such as a memory) in the die groups. The DC/AC testing includes signal testing of pins of the first die group and the second die group and power supply pins, as well as judging whether direct currents and voltage parameters meet the design specifications. The RF testing is aimed at the die group in the CoW unit (if the die group is an RF integrated circuit) to detect logic functions of an RF module. Other function testing is used to judge whether other important or customized functions and properties of the first die group and the second die group meet the design specifications.

The test result of the entire wafer will be formed into a wafer map file, and data is reduced to a datalog. The wafer map records the yield, test time, number of errors per class, and location of CoW units, and the datalog includes specific test results. By analyzing these pieces of data, the number and location of defective CoW units may be identified.

Going back to FIG. 12, then, the step 1204 is performed to cut each computing layer and line layer in CoW units. In this paper, the computing layer and line layer in CoW units are called CoW dies. In this step, CoW dies on the wafer 1401 are cut off, and according to the result of the wafer testing, CoW dies including qualified CoW units are left, and CoW dies including defective CoW units are eliminated.

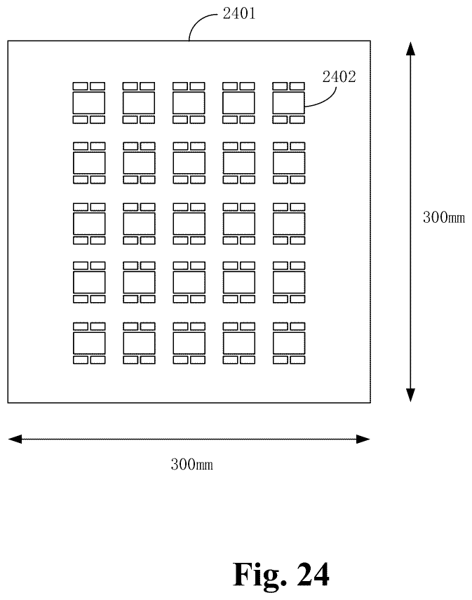

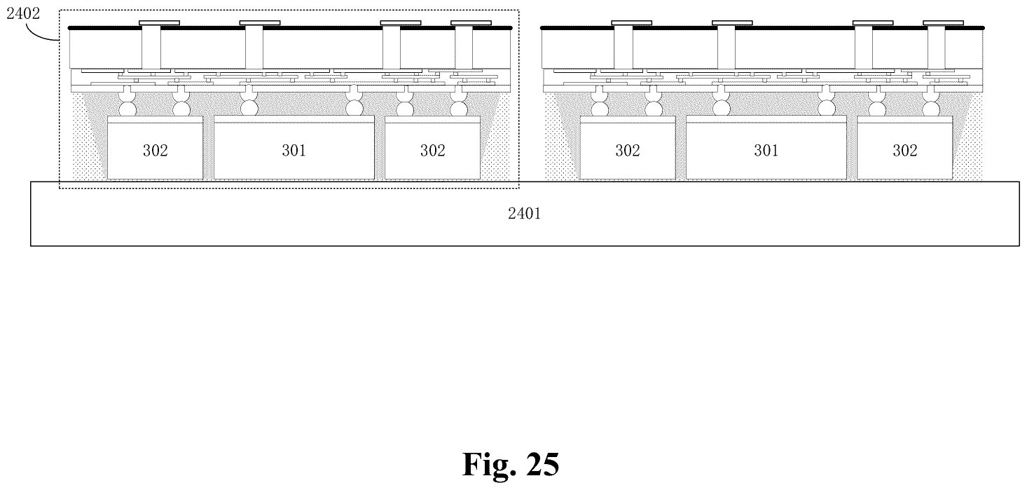

In step 1205, a plurality of CoW dies are bonded on second glass. During bonding, the number and location of the CoW dies are planned according to the functions and requirements of the accelerator. For example, a 5×5 CoW die array is set within the range of 300 mm×300 mm. As shown in FIG. 24, 25 CoW dies 2402 are bonded on 300 mm×300 mm second glass 2401 to form a 5×5 CoW unit array. FIG. 25 is a cutaway view after the CoW dies 2402 are bonded on the second glass 2401.

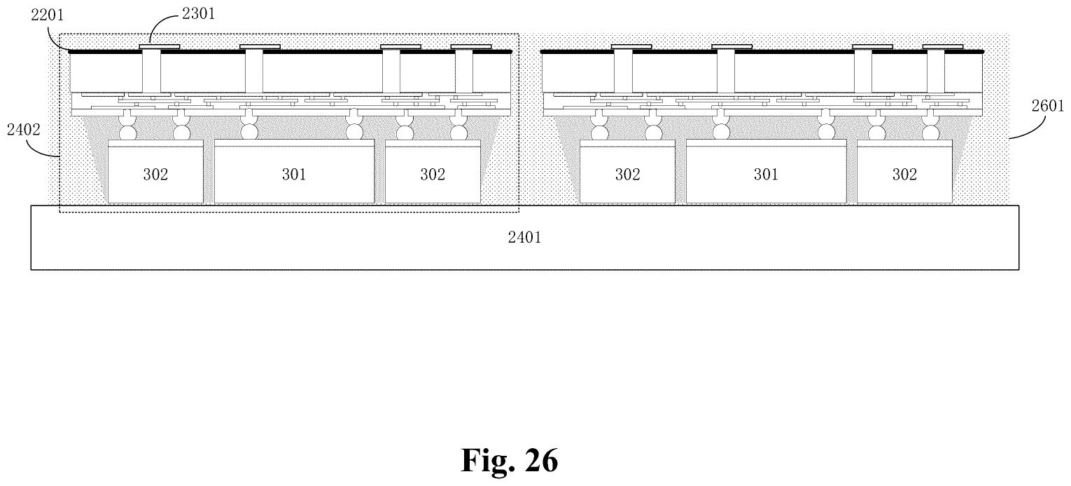

In step 1206, a laminated plastic is generated to cover the CoW dies. FIG. 26 is a structural diagram after a laminated plastic is generated. As shown in FIG. 26, a laminated plastic 2601 covers all CoW dies 2402 to protect the overall structure.

In step 1207, the laminated plastic 2601 covering the plurality of CoW dies is ground to expose surfaces of a plurality of through-silicon vias. As shown in FIG. 26, the insulating layer 2201 and the metal points 2301 are removed after the laminated plastic 2601 is ground, so that the surfaces (top surfaces) of the through-silicon vias 1402 are exposed to air.

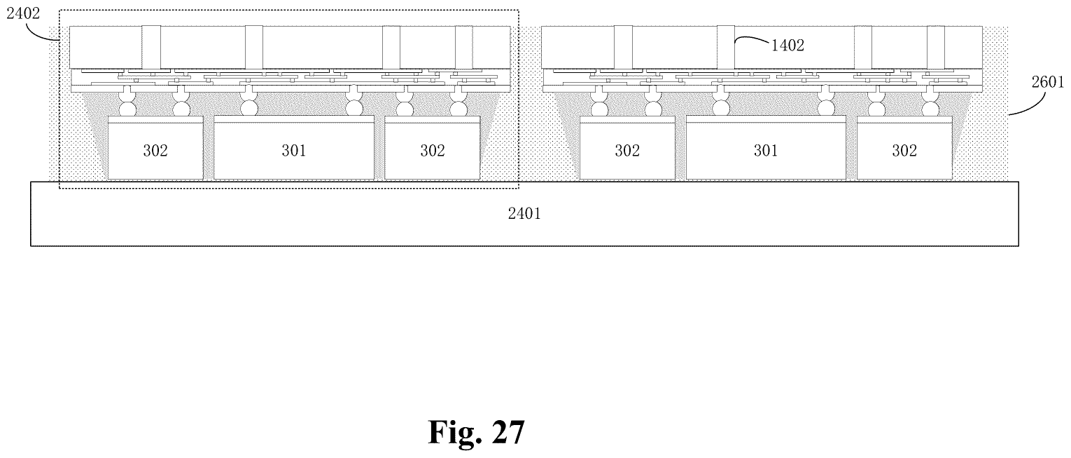

In step 1208, chemical-mechanical polishing is performed on the ground surfaces. FIG. 27 is a cutaway view after chemical-mechanical polishing.

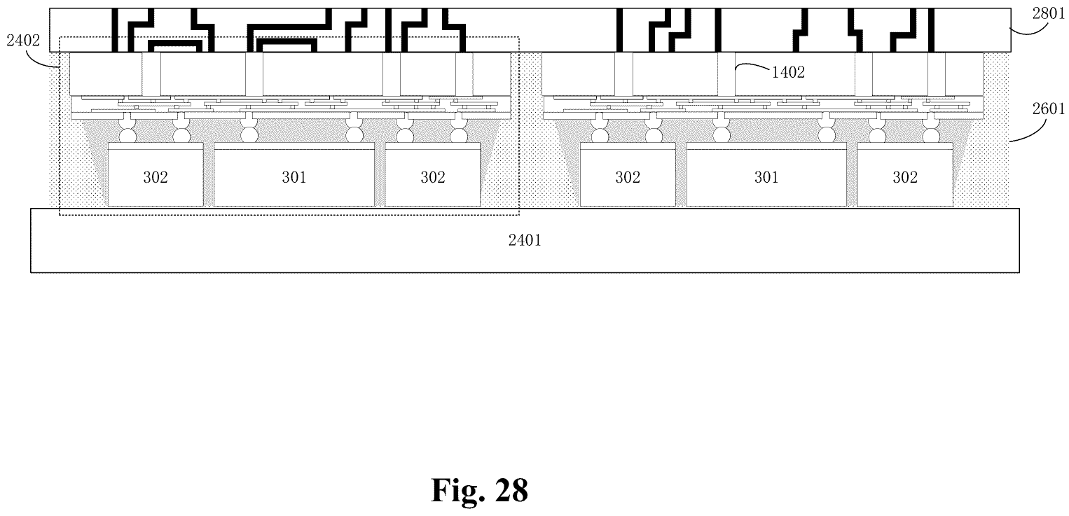

In step 1209, a second part of the line layer is generated. In this step, a second re-distribution layer is generated on the other side of the plurality of through-silicon vias to complete the entire line layer. FIG. 28 is a cutaway view after the entire line layer is completed. The second re-distribution layer 2801 in the figure is the second re-distribution layer 810 in FIG. 8.

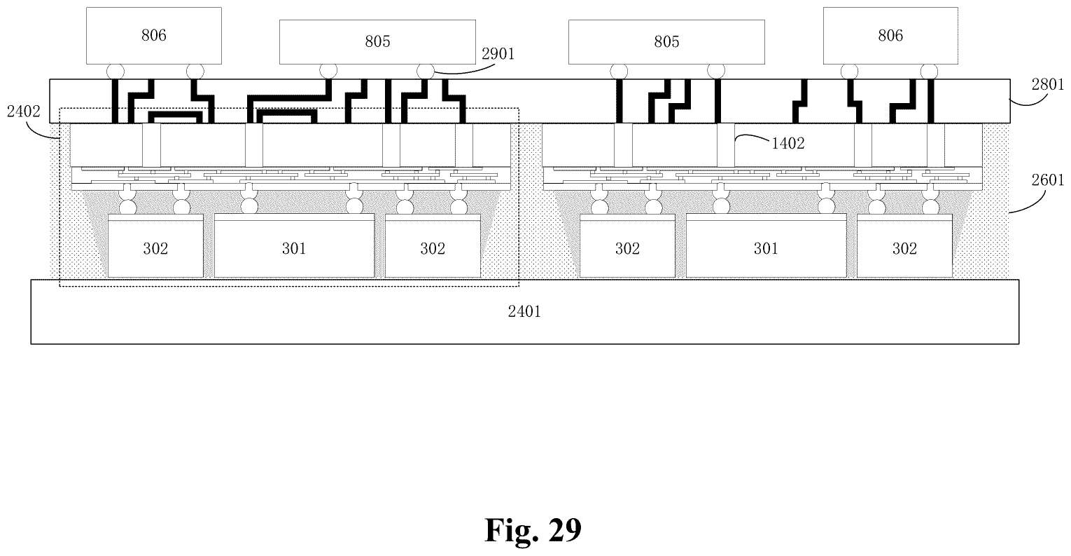

In step 1210, a module layer is generated on the other side of the line layer. First, a solder ball is formed on the second re-distribution layer, then a power module die group and an interface module die group are bonded on the chip, and the solder ball electrically connects the second re-distribution layer with the power module die group and the interface module die group. FIG. 29 is a cutaway view after a module layer is generated. The figure shows that a solder ball 2901 (the solder ball 812 in FIG. 8) electrically connects the second re-distribution layer 2801 with the power modules 805 of the power module die group and the interface modules 806 of the interface module die group. The power module die group supplies power to the first die group and the second die group through the line layer. The first die group and the second die group output a computing result via the interface module die group through the line layer.

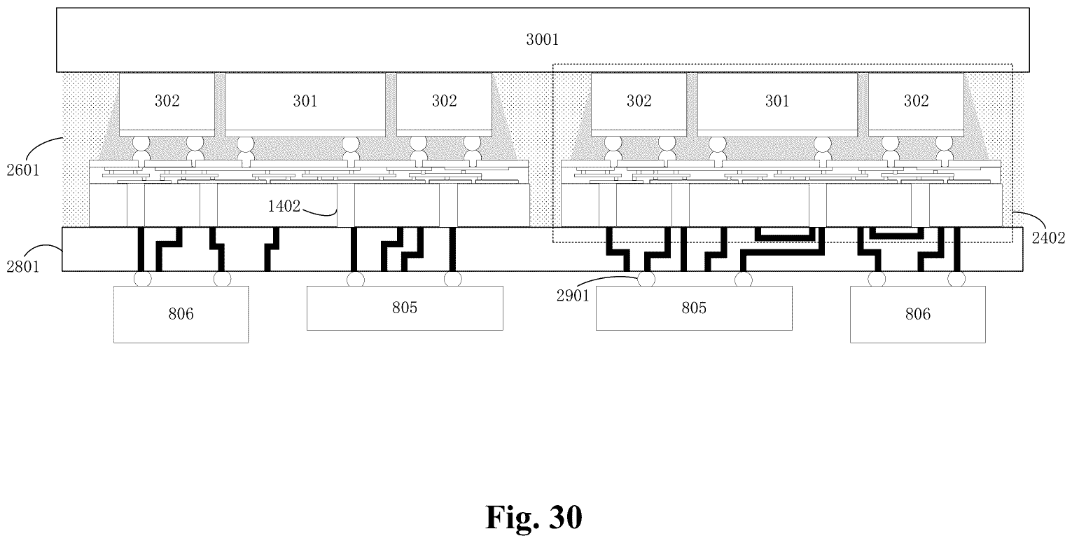

In step 1211, the second glass is flipped and removed. In step 1212, a heat dissipation module is bonded on the computing layer side. FIG. 30 is a cutaway view after a heat dissipation module 3001 (the heat dissipation module 804 in FIG. 8) is bonded. So far, the entire accelerator structure has been completed.

In step 1213, according to the InFO_SoW technology, the structure of FIG. 30 is packaged, so that a single accelerator chip is realized.

The above is an explanation taking an example of generating the structure in FIG. 8. If the structure in FIG. 9 is to be generated, since the difference between the structure in FIG. 9 and that in FIG. 8 is only the through-silicon via in the line layer, only the step 1301 in the above processes is required to be omitted, and the other steps are executed to generate the structure in FIG. 9.

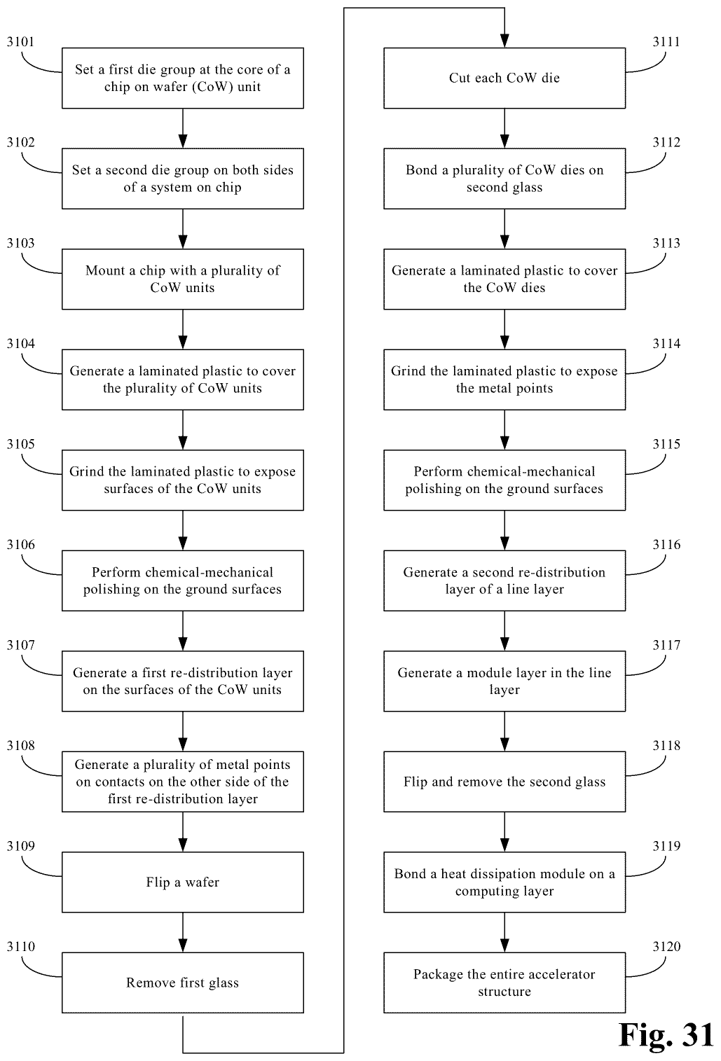

Another embodiment of the present disclosure is also a method for generating an accelerator structure. FIG. 31 is a flowchart of this embodiment. The CoW unit of this embodiment also includes a first die group and a second die group, where the first die group is the above-mentioned system on chip, and the second die group is the above-mentioned memory.

In step 3101, a first die group (a system on chip) is set at the core of a CoW unit. In step 3102, a second die group (a memory) is set on both sides of the system on chip. In step 3103, a chip is mounted with a plurality of CoW units on first glass. In step 3104, a laminated plastic is generated to cover the plurality of CoW units. In step 3105, the laminated plastic is ground to expose surfaces of the plurality of CoW units. In step 3106, chemical-mechanical polishing is performed on the ground surfaces. In step 3107, a first re-distribution layer is generated on the surfaces of the CoW units, where contacts of the first die group and the second die group are electrically in direct contact with contacts of the first re-distribution layer.

Wafer testing is then performed. In step 3108, a plurality of metal points are generated on contacts on the other side of the first re-distribution layer. These metal points are appropriately electrically contacted with at least one of the contacts of the first re-distribution layer to serve as wafer testing points for electrical contact of a probe.

After the wafer testing, then, step 3109 is performed to flip the wafer, so that first glass is on top. In step 3110, the first glass is removed. In step 3111, each CoW die is cut. In step 3112, a plurality of qualified CoW dies are bonded on second glass. In step 3113, a laminated plastic is generated to cover the CoW dies. In step 3114, the laminated plastic covering the plurality of CoW dies is ground to expose metal points. In step 3115, chemical-mechanical polishing is performed on the ground surfaces. In step 3116, a second re-distribution layer of a line layer is generated, where contacts of the second re-distribution layer are electrically connected to the metal points to complete the entire line layer. In step 3117, a module layer is generated in the line layer. First, a solder ball is formed on the second re-distribution layer, then a power module die group and an interface module die group are bonded on the chip, and the solder ball electrically connects the second re-distribution layer with the power module die group and the interface module die group. In step 3118, the second glass is flipped and removed. In step 3119, a heat dissipation module is bonded on a computing layer. In step 3120, the entire accelerator structure is packaged, so that a single accelerator chip is realized.

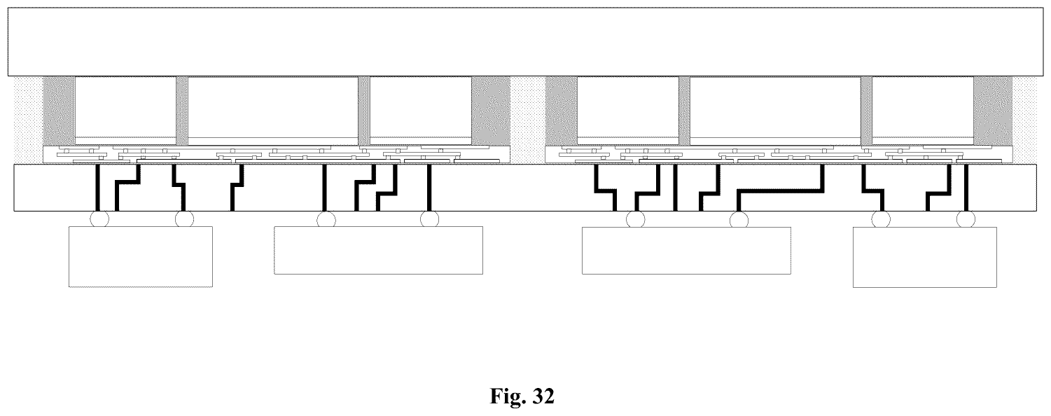

FIG. 32 is a cutaway view of the accelerator structure of this embodiment. The difference from the accelerator structure in FIG. 30 is that there is no bump on the first re-distribution layer in this embodiment, and the contacts of the first die group and the second die group are directly electrically contacted with the contacts of the first re-distribution layer. Therefore, it is not necessary to fill the bottom of the first die group and the second die group with sealant, but to cover the CoW unit with the laminated plastic. Moreover, no through-silicon via is generated in the line layer in this embodiment, and the first re-distribution layer is connected with the second re-distribution layer without the use of the through-silicon via, thereby saving the process of generating the through-silicon via.

Another embodiment of the present disclosure is a computer-readable storage medium, on which a computer program code for generating an accelerator structure is stored, where when the computer program code is run by a processing apparatus, the methods shown in FIG. 12, FIG. 13, FIG. 15, FIG. 19, and FIG. 31 are performed. Another embodiment of the present disclosure is a computer program product, including a computer program for generating an accelerator structure, where steps of the methods shown in FIG. 12, FIG. 13, FIG. 15, FIG. 19, and FIG. 31 are implemented when the computer program is executed by a processor. Another embodiment of the present disclosure is a computer apparatus, including a memory, a processor, and a computer program stored in the memory, where the processor executes the computer program to implement steps of the methods shown in FIG. 12, FIG. 13, FIG. 15, FIG. 19, and FIG. 31.

Due to the rapid development in the chip field, especially the demand for super-large computing power of the accelerator in the artificial intelligence field, the present disclosure integrates CoW technology into InFO_SoW technology to realize large-scale integration of chips. The present disclosure represents the development trend in the chip field, especially in the artificial intelligence accelerator field. In addition, the present disclosure utilizes the chip vertical integration capability of the CoW technology to stack dies vertically to form a die group. Then, the present disclosure utilizes the SoW technology to spread out the die group horizontally, so that a processor core (the aforementioned system on chip) in the die group is arranged in three dimensions in the accelerator, and each processor core may cooperate with other adjacent processors in three dimensions. As such, the ability and speed of the accelerator to process data are greatly improved, and the technical effect of integrating super-large computing power is achieved.

It should be explained that for the sake of brevity, the present disclosure describes some method and embodiments thereof as a series of actions and combinations thereof, but those skilled in the art may understand that the solution of the present disclosure is not limited by the order of actions described. Therefore, according to the present disclosure or under the teaching of the present disclosure, those skilled in the art may understand that some steps of the method and embodiments thereof may be performed in a different order or simultaneously. Further, those skilled in the art may understand that the embodiments described in the present disclosure may be regarded as optional embodiments; in other words, actions and units involved thereof are not necessarily required for the implementation of a certain solution or some solutions of the present disclosure. Additionally, according to different solutions, descriptions of some embodiments of the present disclosure have their own emphases. In view of this, those skilled in the art may understand that, for a part that is not described in detail in a certain embodiment of the present disclosure, reference may be made to related descriptions in other embodiments.

For specific implementations, according to the present disclosure and under the teaching of the present disclosure, those skilled in the art may understand that several embodiments disclosed in the present disclosure may be implemented in other ways that are not disclosed in the present disclosure. For example, for units in the aforementioned electronic device or apparatus embodiment, the present disclosure divides the units on the basis of considering logical functions, but there may be other division methods during actual implementations. For another example, a plurality of units or components may be combined or integrated into another system, or some features or functions in the units or components may be selectively disabled. In terms of a connection between different units or components, the connection discussed above in combination with drawings may be direct or indirect coupling between the units or components. In some scenarios, the direct or indirect coupling relates to a communication connection using an interface, where the communication interface may support electrical, optical, acoustic, magnetic, or other forms of signal transmission.

In some other implementation scenarios, the integrated unit may be implemented in the form of hardware. The hardware may be a specific hardware circuit, which may include a digital circuit and/or an analog circuit, and the like. A physical implementation of a hardware structure of the circuit includes but is not limited to a physical component. The physical component includes but is not limited to a transistor, or a memristor, and the like. In view of this, various apparatuses (such as the computing apparatus or other processing apparatus) described in the present disclosure may be implemented by an appropriate hardware processor, such as a CPU, a GPU, an FPGA, a DSP, and an ASIC, and the like. Further, the storage unit or the storage apparatus may be any appropriate storage medium (including a magnetic storage medium or a magneto-optical storage medium, and the like), such as a resistive random access memory (RRAM), a DRAM, a static random access memory (SRAM), an enhanced dynamic random access memory (EDRAM), a high bandwidth memory (HBM), a hybrid memory cube (HMC), a read only memory (ROM), and a random access memory (RAM), and the like.

The foregoing may be better understood according to following articles:

Article A1. An accelerator structure, including: a computing layer, which is provided with a plurality of chip on wafer (CoW) units, each of which includes a first die group and a second die group; a module layer, which is provided with a power module die group and an interface module die group; and a line layer, which is arranged between the computing layer and the module layer, where the power module die group supplies power to the first die group and the second die group through the line layer, where the first die group and the second die group output a computing result through the interface module die group via the line layer.

Article A2. The accelerator structure of article A1, further including a heat dissipation module, which is adjacent to the computing layer and is configured to dissipate heat from the plurality of CoW units.

Article A3. The accelerator structure of article A1, where the line layer is provided with a first re-distribution layer configured to electrically connect the first die group and the second die group within each CoW unit.

Article A4. The accelerator structure of article A3, where the line layer is further provided with a through-silicon via and a second re-distribution layer, where the through-silicon via is arranged between the first re-distribution layer and the second re-distribution layer, and the first die group and the second die group are electrically connected with the module layer through the first re-distribution layer, the through-silicon via, and the second re-distribution layer.

Article A5. The accelerator structure of article A4, where each CoW unit is electrically connected to another CoW unit through the first re-distribution layer, the through-silicon via, and the second re-distribution layer.

Article A6. The accelerator structure of article A1, where the interface module die group converts an electrical signal from the first die group or the second die group into an optical signal for output.

Article A7. The accelerator structure of article A1, where the first die group is a system on chip, and the second die group is a memory.

Article A8. The accelerator structure of article A1, where the first die group includes a system on chip and an on-chip memory stacked vertically, and the second die group is a memory.

Article A9. The accelerator structure of article A1, where the first die group includes a first core layer and a second core layer stacked vertically, and the second die group is a memory.

Article A10. The accelerator structure of article A7, article A8, or article A9, where the memory is a high bandwidth memory.

Article A11. The accelerator structure of article A9, where the first core layer includes: a first computing area, which is provided with a first computing circuit, and a first die-to-die area, which is provided with a first transceiver circuit; and the second core layer includes: a second computing area, which is provided with a second computing circuit, and a second die-to-die area, which is provided with a second transceiver circuit, where the first computing circuit and the second computing circuit perform data transmission within the first die group through the first transceiver circuit and the second transceiver circuit.

Article A12. The accelerator structure of article A11, where the first core layer further includes a physical area, which is provided with a physical access circuit configured to access the memory.

Article A13. The accelerator structure of article A11, where the first core layer further includes an input and output area, which is provided with an input and output circuit configured as an interface to electrically connect a first die group of another CoW unit.

Article A14. The accelerator structure of article A13, where the plurality of CoW units are arranged in an array, and a CoW unit near the center of the array transmits an intermediate result to neighboring CoW units for computing until the computing result is computed by the outermost CoW unit, and the computing result is output through the interface module die group.

Article A15. An integrated circuit apparatus, including the accelerator structure according to any of articles A1 to A14.

Article A16. A board card, including the integrated circuit apparatus according to article A15.

Article A17. A method for generating an accelerator structure, including: generating a line layer; generating a computing layer on one side of the line layer, where the computing layer is provided with a plurality of chip on wafer (CoW) units, each of which includes a first die group and a second die group; and generating a module layer on the other side of the line layer, where the module layer is provided with a power module die group and an interface module die group, where the power module die group supplies power to the first die group and the second die group through the line layer, where the first die group and the second die group output a computing result through the interface module die group via the line layer.

Article A18. The method of article A17, where a step for generating the line layer includes: generating a plurality of through-silicon vias on a wafer; generating a first re-distribution layer on one side of the plurality of through-silicon vias; and generating a plurality of bumps on the first re-distribution layer.

Article A19. The method of article A18, where a step for generating the computing layer includes: mounting a chip with the plurality of CoW units, where the first die group and the second die group are electrically contacted with the plurality of bumps respectively.

Article A20. The method of article A19, where the step for generating the computing layer further includes: performing underfill on the first die group and the second die group; and generating a laminated plastic to cover the plurality of CoW units.

Article A21. The method of article A20, where the step for generating the computing layer further includes: grinding the laminated plastic to expose surfaces of the plurality of CoW units; and performing chemical-mechanical polishing on the ground surfaces.

Article A22. The method of article A21, further including: performing wafer testing.

Article A23. The method of article A22, where a step for performing the wafer testing includes: bonding first glass on the surfaces; and flipping the wafer.

Article A24. The method of article A23, where the step for performing the wafer testing further includes: grinding the wafer to expose the plurality of through-silicon vias; and performing chemical-mechanical polishing on the ground wafer.

Article A25. The method of article A24, where the step for performing the wafer testing further includes: depositing an insulating layer on the wafer and exposing the plurality of through-silicon vias; and generating a plurality of metal points on the insulating layer, where the plurality of metal points are electrically contacted with at least one of the plurality of through-silicon vias to serve as wafer testing points.

Article A26. The method of article A21, further including: cutting each computing layer and line layer in CoW units to form a CoW die; bonding a plurality of CoW dies on second glass; and generating a laminated plastic to cover the plurality of CoW dies.

Article A27. The method of article A26, further including: grinding the laminated plastic covering the plurality of CoW dies to expose surfaces of the plurality of CoW dies; and performing chemical-mechanical polishing on the ground surfaces.

Article A28. The method of article A27, where the step for generating the line layer further includes: generating a second re-distribution layer on the other side of the plurality of through-silicon vias.

Article A29. The method of article A28, where the step for generating the module layer includes: forming a solder ball on the second re-distribution layer; and bonding the power module die group and the interface module die group on the chip, where the solder ball electrically connects the second re-distribution layer with the power module die group and the interface module die group.

Article A30. The method of article A29, further including: flipping and removing the second glass; and bonding a heat dissipation module on the side of the computing layer.

Article A31. A computer-readable storage medium, on which a computer program code for generating an accelerator structure is stored, where when the computer program code is run by a processing apparatus, the method according to any of articles A17 to A30 is performed.

Article A32. A computer program product, including a computer program for generating an accelerator structure, where steps of the method according to any of articles A17 to A30 are implemented when the computer program is executed by a processor.

Article A33. A computer apparatus, including a memory, a processor, and a computer program stored in the memory, where the processor executes the computer program to implement steps of the method according to any of articles A17 to A30.

The embodiments of the present disclosure have been described in detail above. The present disclosure uses specific examples to explain principles and implementations of the present disclosure. The descriptions of the above embodiments are only used to facilitate understanding of the method and core ideas of the present disclosure. Simultaneously, those skilled in the art may change the specific implementations and application scope of the present disclosure based on the ideas of the present disclosure. In summary, the content of this specification should not be construed as a limitation on the present disclosure.

1. An accelerator structure, comprising:
a computing layer, which is provided with a plurality of chip on wafer (CoW) units, each of which comprises a first die group and a second die group;
a module layer, which is provided with a power module die group and an interface module die group; and
a line layer, which is arranged between the computing layer and the module layer, wherein
the power module die group supplies power to the first die group and the second die group through the line layer, wherein
the first die group and the second die group output a computing result through the interface module die group via the line layer.

2. The accelerator structure of claim 1, further comprising a heat dissipation module, which is adjacent to the computing layer and is configured to dissipate heat from the plurality of CoW units.

3. The accelerator structure of claim 1, wherein the line layer is provided with a first re-distribution layer configured to electrically connect the first die group and the second die group within each CoW unit.

4. The accelerator structure of claim 3, wherein the line layer is further provided with a through-silicon via and a second re-distribution layer, wherein the through-silicon via is arranged between the first re-distribution layer and the second re-distribution layer, and the first die group and the second die group are electrically connected with the module layer through the first re-distribution layer, the through-silicon via, and the second re-distribution layer, wherein each CoW unit is electrically connected to another CoW unit through the first re-distribution layer, the through-silicon via, and the second re-distribution layer.

5. (canceled)

6. The accelerator structure of claim 1, wherein the interface module die group converts an electrical signal from the first die group or the second die group into an optical signal for output.

7. The accelerator structure of claim 1, wherein the first die group is a system on chip, and the second die group is a memory, or
wherein the first die group comprises a system on chip and an on-chip memory stacked vertically, and the second die group is a memory.

8. (canceled)

9. The accelerator structure of claim 1, wherein the first die group comprises a first core layer and a second core layer stacked vertically, and the second die group is a memory.

10. (canceled)

11. The accelerator structure of claim 9, wherein the first core layer comprises:
a first computing area, which is provided with a first computing circuit, and
a first die-to-die area, which is provided with a first transceiver circuit; and
the second core layer comprises:
a second computing area, which is provided with a second computing circuit, and
a second die-to-die area, which is provided with a second transceiver circuit, wherein
the first computing circuit and the second computing circuit perform data transmission within the first die group through the first transceiver circuit and the second transceiver circuit.

12. The accelerator structure of claim 11, wherein the first core layer further comprises a physical area, which is provided with a physical access circuit configured to access the memory, wherein the first core layer further comprises an input and output area, which is provided with an input and output circuit configured as an interface to electrically connect a first die group of another CoW unit.

13. (canceled)

14. The accelerator structure of claim 13, wherein the plurality of CoW units are arranged in an array, and a CoW unit near the center of the array transmits an intermediate result to neighboring CoW units for computing until the computing result is computed by the outermost CoW unit, and the computing result is output through the interface module die group.

15. (canceled)

16. (canceled)

17. A method for generating an accelerator structure, comprising:
generating a line layer;
generating a computing layer on one side of the line layer, wherein the computing layer is provided with a plurality of chip on wafer (CoW) units, each of which comprises a first die group and a second die group; and
generating a module layer on the other side of the line layer, wherein the module layer is provided with a power module die group and an interface module die group, wherein
the power module die group supplies power to the first die group and the second die group through the line layer, wherein
the first die group and the second die group output a computing result through the interface module die group via the line layer.

18. The method of claim 17, wherein a step for generating the line layer comprises:
generating a plurality of through-silicon vias on a wafer;
generating a first re-distribution layer on one side of the plurality of through-silicon vias; and
generating a plurality of bumps on the first re-distribution layer.

19. The method of claim 18, wherein a step for generating the computing layer comprises:
mounting a chip with the plurality of CoW units, wherein the first die group and the second die group are electrically contacted with the plurality of bumps respectively.

20. The method of claim 19, wherein the step for generating the computing layer further comprises:
performing underfill on the first die group and the second die group; and
generating a laminated plastic to cover the plurality of CoW units.

21. The method of claim 20, wherein the step for generating the computing layer further comprises:
grinding the laminated plastic to expose surfaces of the plurality of CoW units; and
performing chemical-mechanical polishing on the ground surfaces.

22. The method of claim 21, further comprising:
performing wafer testing;
bonding first glass on the surfaces; and
flipping the wafer.

23. (canceled)

24. The method of claim 23, wherein the step for performing the wafer testing further comprises:
grinding the wafer to expose the plurality of through-silicon vias;
performing chemical-mechanical polishing on the ground wafer;
depositing an insulating layer on the wafer and exposing the plurality of through-silicon vias; and
generating a plurality of metal points on the insulating layer, wherein the plurality of metal points are electrically contacted with at least one of the plurality of through-silicon vias to serve as wafer testing points.

25. (canceled)

26. The method of claim 21, further comprising:
cutting each computing layer and line layer in CoW units to form a CoW die;
bonding a plurality of CoW dies on second glass;
generating a laminated plastic to cover the plurality of CoW dies;
grinding the laminated plastic covering the plurality of CoW dies to expose surfaces of the plurality of CoW dies; and
performing chemical-mechanical polishing on the ground surfaces.

27. (canceled)

28. The method of claim 27, wherein the step for generating the line layer further comprises:
generating a second re-distribution layer on the other side of the plurality of through-silicon vias;
forming a solder ball on the second re-distribution layer;
bonding the power module die group and the interface module die group on the chip, wherein
the solder ball electrically connects the second re-distribution layer with the power module die group and the interface module die group;
flipping and removing the second glass; and
bonding a heat dissipation module on the side of the computing layer.

29-33. (canceled)
